(19) United States
(12) Patent Application Publication
(10) Pub. No.: US 2024/0204129 A1
(43) Pub. Date: Jun. 20, 2024

(54) PASSIVATION OF PHOTOVOLTAIC DEVICES

(71) Applicants: Alliance for Sustainable Energy, LLC, Golden, CO (US); Tandem PV, Inc., Palo Alto, CA (US)

(72) Inventors: Joseph Matthew LUTHER, Boulder, CO (US); Kyle James REITER, Denver, CO (US); Rosemary Claire BRAMANTE, Lakewood, CO (US); Colin David BAILIE, Morgan Hill, CA (US); Chris EBERSPACHER, Palo Alto, CA (US); Timothy Sean GEHAN, Mountain View, CA (US); David Cale MALONEY, Commerce City, CO (US); Marinus Franciscus Antonius Maria VAN HEST, Golden, CO (US)

(21) Appl. No.: 18/523,000

(22) Filed: Nov. 29, 2023

Related U.S. Application Data
(60) Provisional application No. 63/428,487, filed on Nov. 29, 2022.

(51) Int. Cl. H01L 31/18; H01L 31/048; H01L 31/05; H10K 30/40

(52) U.S. Cl. CPC H01L 31/1868; H01L 31/048; H01L 31/05; H10K 30/40

(57) ABSTRACT

The present disclosure relates to a photovoltaic device that includes a first contact layer having a first thickness, a first charge transport layer (CTL) having a second thickness positioned over a surface of the first contact layer, an absorber layer having a third thickness positioned over a surface of the first CTL, a second CTL having a fourth thickness positioned over a surface of the absorber layer, a second contact layer having fifth thickness positioned over a surface of the second CTL, a barrier layer having a sixth thickness, an encapsulation layer, and a first scribe line defined by at least one surface. Further, at least a portion of the barrier layer is positioned between the encapsulation layer and the second CTL, the at least one surface of the scribe line comprises at least a portion of the third thickness, fourth thickness, fifth thickness, and/or at least a portion of the second thickness, and the barrier layer is disposed over at least a portion of the at least one surface formed by the first scribe line.

### CROSS-REFERENCE TO RELATED APPLICATIONS

This application claims priority from U.S. Provisional Patent Application No. 63/428,487 filed on Nov. 29, 2022, the contents of which are incorporated herein by reference in their entirety.

### CONTRACTUAL ORIGIN

This invention was made with government support under Contract No. DE-AC36-08GO28308 awarded by the Department of Energy. The government has certain rights in the invention.

### BACKGROUND

Perovskite solar cells have attracted attention for being easy to construct and yielding high conversion efficiencies. Yet for commercialization of the technology, full modules, not just individual cells, must exhibit long term durability/stability in each installation location. Large area modules require the perovskite layer to be precisely scribed into smaller area regions and linked together in series and/or in parallel to deliver usable voltages and minimize resistance losses. Scribe sets are typically spaced 5-10 millimeters apart and extend the long dimension of the module. The “P3” scribe is generally performed with a metal stylus or with a high-power laser, which substantially removes the backside electrode and often also the perovskite and layers between, creating a vulnerability that has been noted to be a nucleus for rapid degradation. The laser, and even mechanical scribing systems, exposes layers within the stack and may damage the perovskite layer via heating or ablation. Thus, there remains a need for compositions, devices, and/or methods that can minimize and/or offset the possible negative consequences resulting from the application of scribe lines to perovskite photovoltaic devices.

### SUMMARY

An aspect of the present disclosure is a photovoltaic device that includes a first contact layer having a first thickness, a first charge transport layer (CTL) having a second thickness positioned over a surface of the first contact layer, an absorber layer having a third thickness positioned over a surface of the first CTL, a second CTL having a fourth thickness positioned over a surface of the absorber layer, a second contact layer having fifth thickness positioned over a surface of the second CTL, a barrier layer having a sixth thickness, an encapsulation layer, and a first scribe line defined by at least one surface. Further, at least a portion of the barrier layer is positioned between the encapsulation layer and the second CTL, the at least one surface of the scribe line comprises at least a portion of the third thickness, fourth thickness, fifth thickness, and/or at least a portion of the second thickness, and the barrier layer is disposed over at least a portion of the at least one surface formed by the first scribe line.

In some embodiments of the present disclosure the photovoltaic device may further include a second scribe line defined by at least one surface, where the at least one surface of the second scribe line includes at least a portion of the second thickness, third thickness, fourth thickness, and fifth thickness, and the barrier layer is disposed over at least a portion of the at least one surface of the second scribe line. In some embodiments of the present disclosure, the at least one surface of the first scribe line may include a portion of the first contact layer, first CTL layer, the absorber layer, second CTL layer, and second contact layer.

In some embodiments of the present disclosure, the absorber layer may have a composition that includes ABX₃, where A is a first cation, B is a second cation, and X includes at least one halide. In some embodiments of the present disclosure, the second cation may include at least one of tin and/or lead. In some embodiments of the present disclosure, the first cation may include at least one of formamidinium (FA), methylammonium (MA), and/or cesium.

In some embodiments of the present disclosure, the barrier layer may include at least one of a metal oxide, a polymer, a resin, an aryl ammonium halide, an alkyl ammonium halide, and/or lead sulphate. In some embodiments of the present disclosure, the metal oxide may include at least one of aluminum oxide, silicon oxide, tin oxide, zirconium oxide, and/or titanium oxide. In some embodiments of the present disclosure, the aryl ammonium halide may include at least one of phenethylammonium iodide (PEAI), 1-(ammonium acetyl)pyrene (PEY), and/or dodecyl ammonium-chloride (DACI).

In some embodiments of the present disclosure, the barrier layer may have a thickness between 20 nm and 1500 nm. In some embodiments of the present disclosure, the barrier layer may have a transmittance of greater than 80% at wavelengths greater than 700 nm as measured through the thickness of the barrier layer. In some embodiments of the present disclosure, the photovoltaic device may further include a buffer layer positioned between the absorber layer and the second contact layer, where the buffer layer includes an oxysalt. In some embodiments of the present disclosure, the second charge transport layer may include a fullerene. In some embodiments of the present disclosure, the absorber layer may include at least one of a perovskite, silicon, a III-V alloy, an organic photovoltaic material, a dye-sensitized material, a copper indium gallium selenide alloy, and/or a cadmium telluride alloy. In some embodiments of the present disclosure, the barrier layer may include a material that is insoluble in water.

An aspect of the present disclosure is a method of fabricating a photovoltaic device stack, where the method includes forming a barrier layer on a photovoltaic device layer stack, where the device layer stack includes a first contact layer having a first thickness, a first charge transport layer (CTL) having a second thickness positioned over a surface of the first contact layer, an absorber layer having a third thickness positioned over a surface of the first CTL, a second CTL having a fourth thickness positioned over a surface of the absorber layer, a second contact layer having fifth thickness positioned over a surface of the second CTL, and a first scribe line defined by at least one surface. Further, the at least one surface of the first scribe line includes at least a portion of the third thickness, fourth thickness, fifth thickness, and/or at least a portion of the second thickness, the barrier layer includes at least one of a metal oxide, a polymer, a resin, an aryl ammonium halide, an alkyl ammonium halide, and/or lead sulphate, and the barrier layer is formed over at least a portion of the at least one surface of the first scribe line.

In some embodiments of the present disclosure, the device stack may further include a second scribe line, where the second scribe line may be defined by at least one surface, the at least one surface of the second scribe line includes at least a portion of the first thickness, the second thickness, the third thickness, the fourth thickness, and/or the fifth thickness, and the barrier layer is disposed over at least a portion of the at least one surface of the second scribe line. In some embodiments of the present disclosure, the barrier layer may include the metal oxide, and the metal oxide comprises aluminum oxide, silicon oxide, tin oxide, zirconium oxide, titanium oxide, or a combination thereof.

In some embodiments of the present disclosure, the barrier layer may have a thickness between 20 nm and 1500 nm, and the barrier layer may have a transmittance of greater than 80% at wavelengths greater than 700 nm as measured through the thickness of the barrier layer. In some embodiments of the present disclosure, the barrier layer may include a material that is insoluble in water.

### BRIEF DESCRIPTION OF DRAWINGS

Some embodiments are illustrated in referenced figures of the drawings. It is intended that the embodiments and figures disclosed herein are to be considered illustrative rather than limiting.

FIG. 1A illustrates an exemplary device stack that includes multiple layers that may be used in a fully functioning solar cell and/or solar module, according to some embodiments of the present disclosure.

FIG. 1B illustrates an exemplary device stack as tested experimentally and described herein, according to some embodiments of the present disclosure. Such a device, without any scribe lines, is referred to herein as a “test stack”.

FIG. 2A illustrates an exemplary scribed test stack, including scribe line P3, as tested experimentally and described herein, according to some embodiments of the present disclosure. This scribed test stack is essentially equivalent to the “test stack” illustrated in FIG. 1B, but with the addition of a P3 scribe line, and is referred to herein as a “scribed test stack”.

FIG. 2B illustrates an exemplary device stack that includes all of the layers that may be used in a fully functioning solar cell and/or solar module, including scribe lines P1, P2, and P3, according to some embodiments of the present disclosure. A device like this, having at least a P3 scribe line and two cells electrically connected in series is referred to herein as a “test module”. In the experiments described herein the first CTL 130 was configured as a HTL and the second CTL 150 was configured as an ETL. However, this is not intended to be limiting; the first CTL 130 may be either an ETL or an HTL and the second CTL 150 may be either an HTL or an ETL.

FIG. 2C illustrates schematic side cross-sectional views of scribe lines, according to some embodiments of the present disclosure.

FIG. 3 illustrates optical transmittance in the ultraviolet and visible ranges (UV-VIS) data for a test stack (see FIG. 1B) of glass substrate/ITO/PTAA/perovskite/Al₂O₃ stack, according to some embodiments of the present disclosure. Test conditions were that a test stack was evaluated from 0 to 1010 hours at intervals when placed without additional heating or cooling under a light equivalent to about 0.7 AM1.5 suns in an ambient air environment (relative humidity [RH]˜30-40%).

FIG. 4 illustrates UV-VIS data for a test stack (see FIG. 1B) of glass substrate/ITO/PTAA/perovskite/polystyrene stack, according to some embodiments of the present disclosure. Test conditions were that a test stack was evaluated from 0 to 1010 hours at intervals when placed without additional heating or cooling under a light equivalent to about 0.7 AM1.5 suns in an ambient air environment (RH˜30-40%).

FIG. 5 illustrates UV-VIS data for a test stack (scc FIG. 1B) of glass substrate/ITO/PTAA/perovskite stack (no barrier layer), according to some embodiments of the present disclosure. Test conditions were that a test stack was evaluated from 0 to 1010 hours at intervals when placed without additional heating or cooling under a light equivalent to about 0.7 AM1.5 suns in an ambient air environment (RH˜30-40%).

FIG. 6 compares the performance, as measured by UV-VIS optical density (OP) versus time for various test stacks (see FIG. 1B) of glass substrate/ITO/PTAA/perovskite/barrier layer, according to some embodiments of the present disclosure. Test conditions were optical density coefficient as measured at 700 nm wavelength as derived from percent transmittance data, as seen in FIGS. 3, 4, and 5. Test stacks were evaluated from 0 to 1010 hours at intervals when placed without additional heating or cooling under a light equivalent to about 0.7 AM1.5 suns in an ambient air environment (RH˜30-40%).

FIG. 7 illustrates photographs of a test stack control and a test stack with the initial super barrier of the combination of CYTOP® and PEIE that was the first barrier layer to withstand 85° C. for over 100 hours and is representative of the clear difference between control and barrier layer test stacks such as illustrated in FIGS. 3 through 6, as they appeared after testing was complete, according to some embodiments of the present disclosure.

FIGS. 8-10 illustrate perovskite-containing scribed test stacks (see FIG. 2A) and the initial testing of the eight barrier materials of choice. FIG. 8 depicts the scribed test stacks after being subjected to a water drop test. FIG. 9 depicts the scribed test stacks from 192 hours to 672 hours on an 85° C. hot plate and is the heat test. FIG. 10 depicts the scribed test stacks from 192 hours to 672 hours when placed under a light at 0.7 AM1.5 suns in the ambient air environment (RH˜30-40%) and is the light test. FIGS. 8-10 show the testing of the eight barrier materials initially chosen whose results led to the down-selection to PMMA, PS, SiOₓ, Al₂O₃, and CYTOP PEIE super barrier as the best barrier material options respectively, as described herein, according to some embodiments of the present disclosure.

FIG. 11 illustrates ten IZO top contact perovskite test modules (see FIG. 2B) before the deposition barrier materials and the same modules post-deposition of respective barrier materials and controls that remained uncoated, according to some embodiments of the present disclosure.

FIG. 12A illustrates SEM images of perovskite-containing test modules (see FIG. 2B) coated with various barrier materials (Al₂O₃, PMMA, PS, and SiOₓ) and filling P2 and P3 scribes, according to some embodiments of the present disclosure. Panel A) SEM image of an Al₂O₃ film fully covering sidewalls and bottom of P2 scribe with a known thickness of 50 nm (30K magnification). Panel B) SEM image of a PMMA film filling P3 scribe with thickness varying from 1.33 μm on top of the module to 1.59 μm in the scribes (20K magnification). Panel C) SEM image of a PS film filling P2 scribe with thickness varying from 1.40 μm on top of the module to 2.07 μm in the scribes (20K magnification). Panel D) SEM image of an SiOₓ film filling P3 scribe with a known thickness of 1000 nm (20K magnification).

FIG. 12B illustrates a larger version of an SEM image of a test module P3 scribe with a barrier layer of SiOₓ with the various layers called out, according to some embodiments of the present disclosure.

FIG. 12C illustrates SEM images of test modules that show filled P3 scribes with SiOₓ and PMMA to depict that the barrier materials fully fills the entire width of the scribe uniformly, with the width of the P3 scribe called out, according to some embodiments of the present disclosure.

FIG. 13 illustrates four barrier materials on blank glass/ITO microscope slides, Al₂O₃, SiOₓ, PMMA, and PS, from left to right, according to some embodiments of the present disclosure.

FIG. 14A illustrates a schematic plan view of a photovoltaic device assembly, according to some embodiments of the present disclosure.

FIG. 14B illustrates a schematic side cross-sectional view of a portion of a photovoltaic device array, according to some embodiments of the present disclosure.

FIG. 14C illustrates a schematic side cross-sectional view of a portion of a photovoltaic device array, according to some embodiments of the present disclosure.

FIG. 15 illustrates a method of fabricating a photovoltaic device assembly according to some embodiments of the present disclosure.

FIGS. 16A-16L illustrate schematic views of a photovoltaic device stack during various stages of fabricating a photovoltaic device according to a method disclosed herein.

To facilitate understanding, identical reference numerals have been used, where possible, to designate identical elements that are common to the figures. It is contemplated that elements and features of one embodiment may be beneficially incorporated in other embodiments without further recitation.

### REFERENCE NUMERALS

100 . . . device
110 . . . first substrate layer
115 . . . second substrate layer
120 . . . first contact layer
130 . . . first charge transport layer (CTL)
140 . . . absorber layer
150 . . . second charge transport layer (CTL)
160 . . . buffer layer
170 . . . second contact layer
180 . . . one or more barrier layers
190 . . . encapsulation layer
P1 . . . first scribe line
P2 . . . second scribe line
P3 . . . third scribe line
P4 . . . fourth scribe line

### DETAILED DESCRIPTION

The embodiments described herein should not necessarily be construed as limited to addressing any of the particular problems or deficiencies discussed herein. References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small, and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, ±5%, or ±1% of a specific numeric value or target. In some embodiments of the present invention, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

The present disclosure relates to barrier layers for devices containing perovskite active layers, i.e., absorber layers. Among other things, some of the barrier layers described herein protect the underlying perovskite structures from degrading due to unwanted exposure to moisture. Further, some of the barrier layers are very effective at preventing and/or minimizing the degradation of perovskites when exposed to heat, light, and/or moisture. Further, as shown herein, some of the materials tested for barrier layers are also very effective at protecting perovskite-containing devices having scribe lines.

In general, the term “perovskite” refers to compositions having a network of corner-sharing BX₆ octahedra resulting in the general stoichiometry of ABX₃. Perovskites, for example metal halide perovskites, may organize into three-dimensional (3D) cubic crystalline structures (i.e., α-phase or α-ABX₃) constructed of a plurality of corner-sharing BX₆ octahedra. In the general stoichiometry for a perovskite, ABX₃, X is an anion, while A and B are cations, typically of different sizes. A perovskite having an α-phase structure may be further characterized by eight BX₆ octahedra surrounding a central A-cation, where each octahedra is formed by six X-anions surrounding a central B-cation and each of the octahedra are linked together by “corner-sharing” of anions, X.

A perovskite in the α-phase may be visualized as a cubic unit cell, where the B-cation is positioned at the center of the cube, an A-cation is positioned at each corner of the cube, and an X-anion is face-centered on each face of the cube. The X-anions and the B-cations of a perovskite in the α-phase are aligned along an axis; e.g., where the angle at the X-anion between two neighboring B-cations is exactly 180 degrees, referred to herein as the tilt angle. However, a perovskite may assume other corner-sharing crystalline phases having tilt angles not equal to degrees. For example, a perovskite may also assume a tetragonal crystalline phase (i.e., β-ABX₃) and/or an orthorhombic crystalline phase (i.e., γ-ABX₃), where the adjacent octahedra are tilted relative to the reference axes a, b, and c. In addition, the elements used to construct a perovskite, as described above, A-cations, B-cations, and X-anions, may result in 3D non-perovskite structures; i.e., structures where neighboring BX₆ octahedra are not X-anion corner-sharing and/or do not have a unit structure that simplifies to the ABX₃ stoichiometry. One example of a non-perovskite structure is structure characterized by face-sharing BX₆ octahedra resulting in a hexagonal crystalline structure and a second example of a non-perovskite structure is characterized by edge-sharing BX₆ octahedra resulting in an orthorhombic crystalline structure.

Further, the elements used to construct a perovskite, as described above, A-cations, B-cations, and X-anions, may result in non-3D (i.e., lower dimensional structures) perovskite-like structures such as two-dimensional (2D) structures, one-dimensional (1D) structures, and/or zero-dimensional (0D) structures. For simplification, as used herein the term “perovskite” will refer to each of these various structures. Thus, unless specified otherwise, the term “perovskite” as used herein includes each of a true corner-sharing ABX₃ perovskite, as well as perovskite-like compositions having 0D, 1D, and/or 2D structures. Some of the barrier layers described herein are shown to be very effective at preventing the degradation of perovskites to non-perovskite structures, due to long-term exposure to moisture, heat, and/or light. Further, although much of present disclosure focuses on the use of barrier layers to the benefit of perovskite-containing devices, it is envisioned that at least some of the same barriers may be used to protect other semiconductors and/or photovoltaic materials from moisture, heat, and/or light.

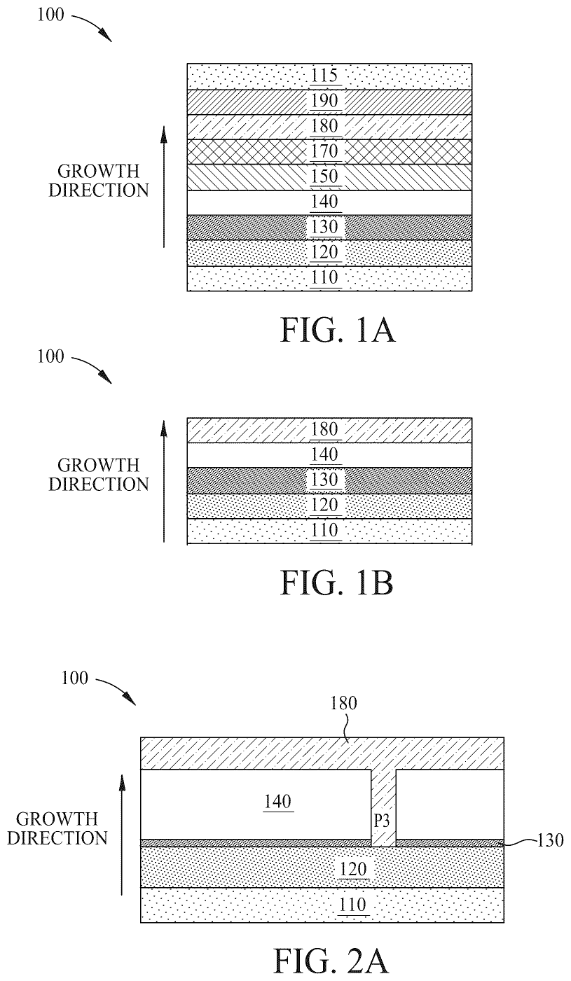

FIG. 1A illustrates an exemplary device stack that includes multiple layers that may be used in a fully functioning solar cell and/or solar module. In some embodiments of the present disclosure, a device 100, e.g., a solar cell, having an absorber layer 140 that is protected by one or more barrier layers 180 may have one or more additional layers, in addition to the absorber layer 140 and one or more barrier layers 180. This device is illustrated for exemplary purposes, showing the various layers that might be included in a solar cell device stack. For example, a device 100 may include, in order, a first substrate layer 110, a first contact layer 120, a first charge transport layer 130, an absorber layer 140 (e.g., a perovskite layer), a second charge transport layer 150, a second contact layer 170, one or more barrier layers 180, an encapsulant layer 190, and a second substrate layer 115.

Referring again to FIG. 1A, the device 100 illustrated may be a solar cell, versus a module, in that the device shown may have no scribe lines, such that scribe lines often separate the absorber layer and/or other layers into individual cells on the module. In some embodiments of the present disclosure, the one or more barrier layers 180 may be deposited after the absorber layer 140 is deposited. Thus, the barrier layers 180 described herein may be utilized in inverted or conventional solar cells and in p-i-n or n-i-p solar cells. Further, the barrier layers 180 described herein may be utilized in single junction or multi-junction solar cells. In some embodiments of the present disclosure, one or more barrier layers 180 of a solar cell may be positioned adjacent to a hole transport layer (HTL), an electron transport layer (ETL), and/or an absorber layer 140 (e.g., a perovskite layer).

Thus, a device 100, e.g., a solar cell, utilizing barrier layers 180 like those described herein may be a multilayer, stacked device. For example, a solar cell may include, in order, an absorber layer 140 (e.g., a perovskite layer), a second charge transport layer (CTL) 150 that is an ETL, a second contact layer 170, and the one or more barrier layers 180.

FIG. 1B illustrates an exemplary device for simulating portions of a solar cell (no scribe lines) that was utilized to test the protective efficacy of various barrier layers, as described in more detail below. Referring to FIG. 1B, barrier layers 180 were placed directly in contact with an underlying perovskite absorber layer 140, with no extra layers positioned between, such as a second contact layer and/or a second charge transport layer. This simplification of the device stack eliminated the potential protective contributions provided by layers other than the barrier layers and simplified the analysis to a direct comparison of the various barrier materials tested. Referring again to FIG. 1B, a device using this architecture, and tested in the lab, is referred to herein as a “test stack”.

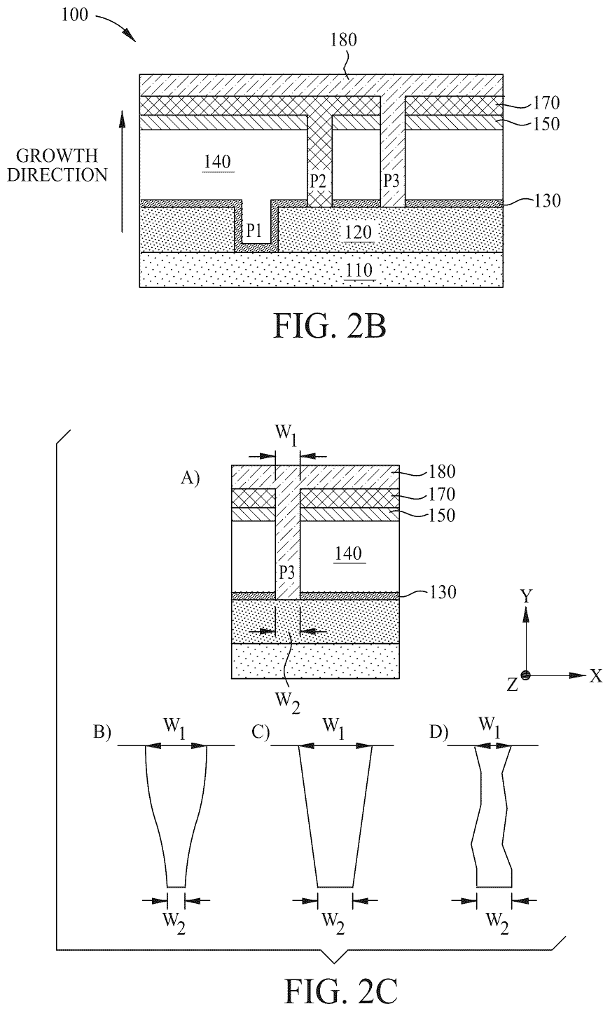

FIG. 2A illustrates a similar simplified device stack used for testing “scribed test stack”. Scribed test stacks were essentially identical to regular test stacks, as illustrated in FIG. 1B, except with the addition of a scribe line designated P3. The simplified scribed test stack architecture, like the test stack illustrated in FIG. 1B, was constructed to simplify the evaluation of the effectiveness of the various barrier layers to coat not just the surface of the underlying perovskite layer, but also protect the perovskite exposed by P3 scribe lines.

In addition, fully functional devices were tested with barrier layers, similar to that shown in FIG. 1A, but in the absence of an encapsulant layer 190 or a second substrate layer 115, and with the addition of scribe lines.

FIG. 2B illustrates an exemplary device stack that includes all of the layers that may be used in a fully functioning solar cell and/or solar module, including two additional scribe lines PI and P2, in addition to P3, according to some embodiments of the present disclosure. A device like this, having at least a P3 scribe line and two cells electrically connected in series is referred to herein as a “test module”. In the experiments described herein the first CTL 130 was configured as a HTL and the second CTL 150 was configured as an ETL. However, this is not intended to be limiting; the first CTL 130 may be either an ETL or an HTL and the second CTL 150 may be either an HTL or an ETL.

In this example, barrier layers 180 were used to cover, coat, and/or fill the P3 scribe lines that were cut into the device 100, mechanically and/or by laser, thereby creating solar cell modules having two solar cells connected in series. Devices utilizing this stack design are referred to herein as “test modules” and each one included each of a first scribe line P1, a second scribe line P2, the third scribe line P3, and two solar cells connected in series. Referring to FIG. 2B, in this example, the third scribe line P3 was filled with one or more barrier materials as described herein, with the third scribe line P3 passing completely through several layers of the device 100, passing through the thicknesses of at least the second contact layer 170 and more typically also through the second CTL 150, the absorber layer 140, the first CTL 130, and perhaps some portion of the first contact layer 120. Although the third scribe line P3 is shown in FIG. 2B to be at least partially filled with a barrier material, depending on the specific solar module design, in some embodiments of the present disclosure, other scribe lines may be at least partially filled with one or more of the barrier layers described herein.

Panel A of FIG. 2C illustrates a portion of the device illustrated In FIG. 2B with emphasis on the P3 scribe line. In this example of a scribe line, it is illustrated as a channel that passes through the thicknesses of each of the first CTL 130, the absorber layer 140, the second CTL 150, and the second contact layer 170. Further, this exemplary scribe line is shown as having walls and/or surfaces that are positioned substantially perpendicular to the alignment of the layers making up the device stack. In addition, the exemplary scribe line illustrated in Panel A of FIG. 2C is characterized by a top width, w₁, that is equal to a bottom width, w₂, with all of the intermediate widths of the scribe line also equal to w₁. Thus, the scribe line illustrated in Panel A of FIG. 2C may be described as having a cross-section or profile defined by a first width, w₁, at a first reference point positioned along a reference axis y, and a second width, w₂, at a second reference point positioned along the reference axis y, were w₁ is equal to w₂, and where the two endpoints are connected by a straight line and the resultant sidewall and/or surface of the scribe line is defined by a flat plane. In some embodiments of the present disclosure, a scribe line, e.g., a P3 scribe line, may have surfaces and/or sidewalls that are aligned with axis y, where the y axis is perpendicular to the x axis. However, the scribe line illustrated in Panel A of FIG. 2C is just one possible example of a scribe line for P3 and/or any of the other scribe lines described herein and shown for illustrative purposes.

Referring again to Panel A of FIG. 2C, the barrier layer 180 is deposited on an outer surface of the second contact layer 170 forming a conformal layer that leaves none of the underlying surface of the second contact layer exposed to the environment. In addition, in this example, the material making up the barrier layer 180 completely fills the scribe line and completely covers all of the surfaces that define the channel-like feature of the scribe line, including the bottom surface and the sidewalls. However, as noted below, the barrier layer 180 may conformally coat and only partially fill a formed scribe line.

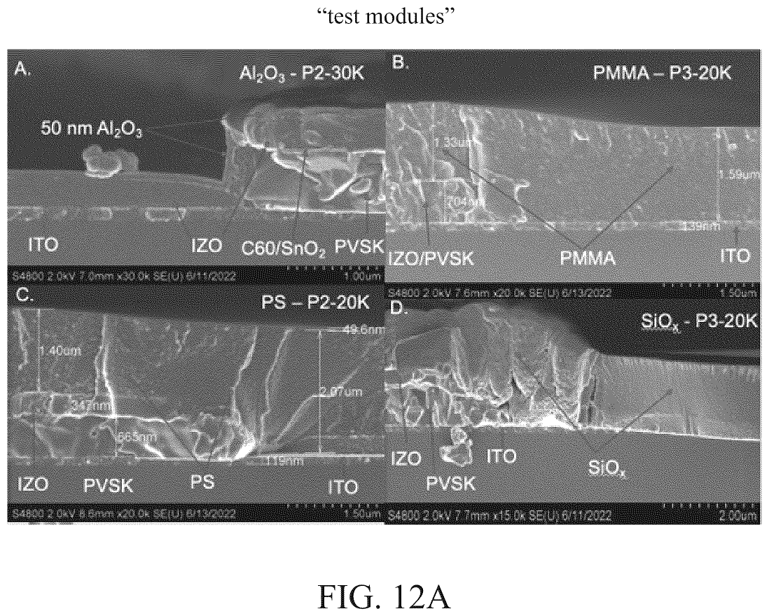

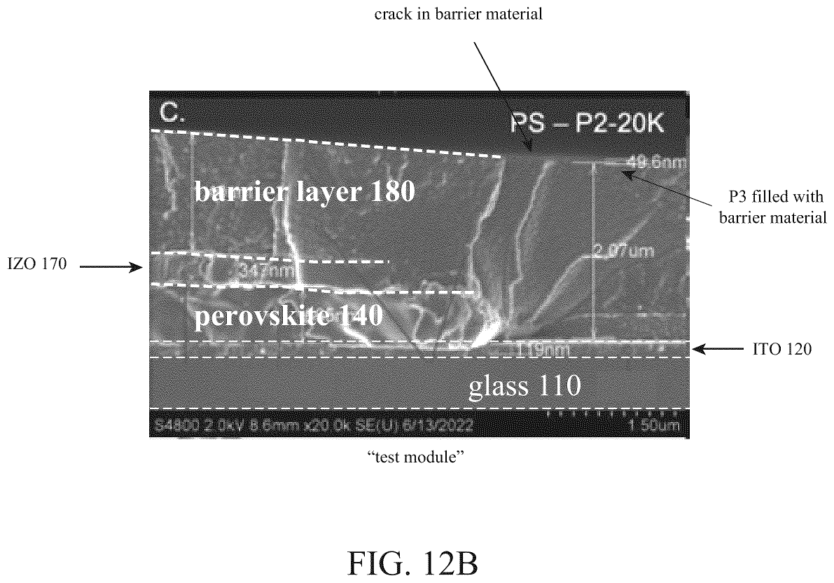

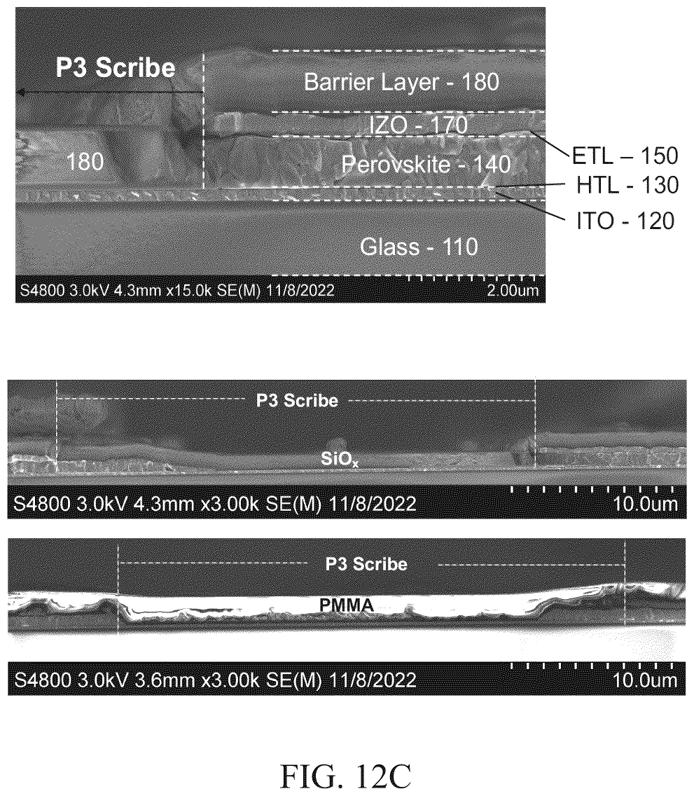

However, a scribe line produced by laser and/or mechanical etching may rarely have surfaces that are positioned perfectly straight and perpendicular to the layers through which the scribe line penetrates. Three additional exemplary profiles for scribe lines are illustrated in Panels B-D of FIG. 2C. Panel C illustrates a scribe line with a profile that is much like the scribe line illustrated in Panel A of FIG. 2C, except that the second width, w₂, is less than the first width, w₁. However, the two endpoints are, like the previous example, connected by straight line, and the resultant sidewalls defining the scribe line are flat, planar surfaces. Panels B and C of FIG. 2C illustrate examples of scribe lines defined by widths that vary as a function of scribe line depth (relative to the y-axis). As shown in Panel B of FIG. 2C, a scribe line may have side walls that are defined by a continuous curve, resulting in sidewalls having non-linear curved surfaces. In this example, the width of the scribe line decreases as a function of scribe line depth. As shown in Panel D of FIG. 2C, a scribe line may have side walls that are defined by an irregular shaped curve, resulting in sidewalls having non-linear curved surfaces and in some cases forming a scribe line where the width, w₂, is greater than the first width, w₁. However, as shown in the SEM image illustrated in FIG. 12B, the side walls of a scribe line may be irregular and not easily described by a simple profile that fits a linear and/or non-linear function. Nevertheless, in each example, for a scribe line to serve its intended purpose, the empty space, void, and/or channel formed by the scribing process will have cross-section, i.e., profile positioned in the XY-plane, defined by a first width, w₁, and a second width, w₂, such that the empty space continues from the first width to the second width, without any physical obstacles that would prevent filling the empty space with barrier layer material. For clarity of discussion purposes, the term a “width of a scribe line”, as used herein to describe a measurable characteristic of a scribe line, is intended to refer to the first width w₁. The first width w₁ is generally defined by the opening formed at the uppermost portion of the scribe line as measure relative to a plane (e.g., XZ plane) that is parallel to uppermost surface through which the scribe line is formed through. In one example, as shown in Panel A of FIG. 2C, the first width w₁ is measured at the opening formed at the top surface of the second contact layer 170.

Referring again to FIGS. 1A and 2B, the exemplary devices having all of the elements for a fully functional solar cell and/or module, e.g., first contact/HTL/absorber layer/ETL/second contact, show barrier layers deposited on the outermost surfaces of the devices. This is not intended to be limiting and barrier materials/layers as described herein may be positioned elsewhere in and/or on a device stack. For example, in some embodiments of the present disclosure, a barrier layer/material may be positioned between a perovskite layer and an adjacent charge transport layer, ETL and/or HTL. In some embodiments of the present disclosure, a barrier layer/material may be positioned between a charge transport layer and a contact layer. The position of a barrier layer/material will depend on the specific device stack architecture and the device's intended use.

Examples of materials shown herein that provide excellent barrier layer properties to both test cells and test modules, as measured by exposure to moisture, heat, and/or light include polystyrene (PS), polydimethylsiloxane (PDMS), polyethylenimine (PEIE); polymethylmethacrylate (PMMA), lead sulphate, phenethylammonium iodide (PEAI), a fluorinated hydrocarbon polymer, and/or a metal oxide, such as silica and/or alumina. In some embodiments of the present disclosure, a device may incorporate at least two barrier layers positioned adjacent to each other, where the material for at least one barrier layer is different from the material of the remaining barrier layers.

Any suitable material may be used for the other layers in the device stack, a solar cell, and/or solar module, and will vary depending on the intended use. For example, at least one of the substrate layers, the first substrate layer 110, the second substrate layer 115, or both, may be constructed using a metal foil, glass, and/or a polymer substrate. In some embodiments of the present disclosure, at least one of the contact layers, the first contact layer 120, the second contact layer 170, or both, may be constructed using a transparent conducting oxide, for example indium zinc oxide, indium tin oxide, tin oxide or fluorine-doped tin oxide. In some embodiments of the present disclosure, at least one of the contact layers, the first contact layer 120, the second contact layer 170, or both, may be constructed using a metal such as aluminum, copper, silver, and/or gold. In some embodiments of the present disclosure, one of the charge transport layers (CTLs), the first CTL 130, the second CTL 150, may be constructed using a hole transport material such as poly[bis(4-phenyl)(2,4,6-trimethylphenyl)amine] (PTAA), [N,N′-bis(4-butylphenyl)-N,N′-bis(phenyl)-benzidine] (Poly-TPD), NiOₓ, and/or a self-assembled monolayer (SAM) of molecules, where the SAM may include a functional group having a carbazole and phosphorous onto a transparent conducting oxide (TCO) or hole transport material as listed. Some examples of SAMs include at least one of [2-(9H-carbazol-9-yl)ethyl]phosphonic acid (2PACz), [4-(9H-carbazol-9-yl)ethyl]phosphonic acid (4PACz), 2-(3,6-dimethyl-9H-carbazol-9-yl)ethyl)phosphonic acid (Me-2PACz), [4-(3,6-dimethyl-9H-carbazol-9-yl)butyl]phosphonic acid (Me-4PACz), [2-(3,6-dimethoxy-9H-carbazol-9-yl)ethyl]phosphonic acid (MeO-2PACz), and/or (4-(3,6-dimethoxy-9H-carbazol-9-yl)butyl)phosphonic acid (McO-4PACz). In some embodiments of the present disclosure, the other CTL, the first CTL 130, the second CTL 150, that is not constructed of a hole transport material may be constructed using an electron transport material, for example a metal oxide such as at least one of TiO₂, SnO₂, Al₂O₃, ZnO, or carbon contacts such as carbon nanotubes, fullerenes (e.g., C₆₀ and or C₇₀), the fullerene derivative [6,6]-phenyl-C₆₁-butyric acid methyl ester (PCBM), with fullerenes used alone or in conjunction with bathocuproine (BCP), or SnO₂. or other metal oxide. All of these materials are provided as examples and are not considered limiting.

In some examples of the present disclosure, an indium tin oxide (ITO) layer may have a thickness between 50 nm and 1000 nm. In some examples of the present disclosure, a PTAA layer or nickel oxide layer may have a thickness between 5 nm and 100 nm. In some examples of the present disclosure, an absorber layer, e.g., a perovskite, may have a thickness between 200 nm and 1500 nm. In some examples of the present disclosure, a layer of C₆₀ may have a thickness between 15 nm and 35 nm. In some examples of the present disclosure, a layer of BCP may have a thickness between 4 nm and 20 nm. In some examples of the present disclosure, a layer of SnO₂ may have a thickness between 4 nm and 30 nm. In some examples of the present disclosure, a layer of IZO may have a thickness between 50 nm and 500 nm. In some examples of the present disclosure, the third scribe line P3 may have a width between 5 μm and 200 μm. In some embodiments of the present disclosure, the third scribe line P3 may have a depth between 100 nm and 3 μm. Further, other materials may be used for any of the layers illustrated in FIGS. 1A, 1B, 2A, and/or 2B, as needed or required for a particular application or use.

Referring again to FIG. 1A, in some embodiments of the present disclosure, a device 100 may include an encapsulant layer 190 positioned adjacent to a barrier layer 180. An encapsulant layer 190 may be constructed using at least one of alumina, SiOₓ, poly(methyl methacrylate) (PMMA), polystyrene (PS), CYTOP® (sec Structure 1 below), or PEIE, and where x is greater than zero and less than or equal to two.

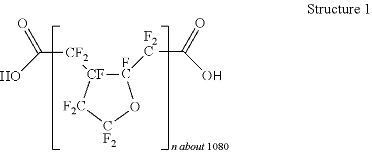

In some embodiments of the present disclosure, the absorber layer 140 of a device, e.g., a solar cell, and/or solar module, may be constructed using a perovskite as described herein. However, devices using other light-absorbing, photovoltaic materials may also take advantage of the concepts and materials described herein, and perovskites are not intended to be limitation. Other examples of absorber materials that may be combined with the barrier layers described herein include silicon (both amorphous and crystalline), III-V materials (both amorphous and crystalline), organic photovoltaic materials (OPV), dye-sensitized solar cells (DSSC), copper indium gallium selenide solar cells (CIGS), and/or cadmium telluride solar cells (CdTe). The barrier layers described herein may be applied to single junction solar cells, tandem solar cells, and multi-junction solar cells.

In some embodiments of the present disclosure, a barrier layer may be provided using an ink that is applied using a solution processing method. Such an ink may include the material and/or precursor material needed to form the barrier, for example at least one of polystyrene (PS), polydimethylsiloxane (PDMS), polyethylenimine (PEIE); polymethylmethacrylate (PMMA), lead sulphate, phenethylammonium iodide (PEAI), and/or a fluorinated hydrocarbon polymer. Further, in some embodiments of the present disclosure, an ink for forming a barrier layer may include at least one liquid component that at least one of suspends and/or dissolves the barrier layer material and/or precursors/reactants needed to form the barrier layer. In some embodiments of the present disclosure, such a liquid may include an acetate, such as at least one of ethyl acetate and/or methyl acetate. In some embodiments of the present disclosure, an ink formulation may include one or more additives, for example one or more viscosity modifiers. An ink for forming one or more barrier layers may be applied using a variety solution processing methods including, for example, blade coating, ink-jet printing, slot-die coating, spray-coating, and/or roll-to-roll gravure printing.

Inks for applying the materials used to construct the barrier layers were initially developed to be inkjet-printed for the directed application of the materials to infill perovskite-containing scribed test modules (see FIG. 2B). However, difficulties and issues with printing reliability led to blanket coating of barrier materials onto perovskite surfaces. So, eventually a list of new inks to be cured into barrier layers as blanket coatings was conceived as described herein, barrier materials 1-8 (listed below) were solution processed and blade coated onto test cells (scribed and unscribed) and onto test modules. Barrier materials 7 and 8, SiOₓ and Al₂O₃, were deposited by thermal evaporation and atomic layer deposition, respectively.

To test the effectiveness of the various barrier layers, three different tests were conceived to accelerate degradation of test cells. The first test was a water drop test, which involved dropping deionized (DI) water droplets, each droplet having a total volume of about 12 μL, directly onto both bare perovskite layers, and perovskite layers covered with at least one barrier layer to visually test how quickly degradation occurred due to exposure to the DI water. The second barrier material test was a heat test, which involved placing perovskite samples, bare and protected, directly on a hot plate set to a temperature of about 85° C. and the respective times for conversion from black to yellow (or clear) was measured. The third barrier test conceived was a light soak test, which was performed by placing perovskite samples, bare and protected, under an AM1.5 spectrum lamp (at about 0.7 suns) at ambient air conditions and the respective times for converting from the black phase to the yellow (or clear) phase were measured, which indicated degradation of the perovskite crystal phase. These three tests provided a means to quantitatively measure and compare the effectiveness of the various barrier materials to reduce degradation of the underlying perovskite as determined by, among other things, the conversion of the perovskite to lead iodide, corresponding to the material's appearance changing from black to pale yellow or clear.

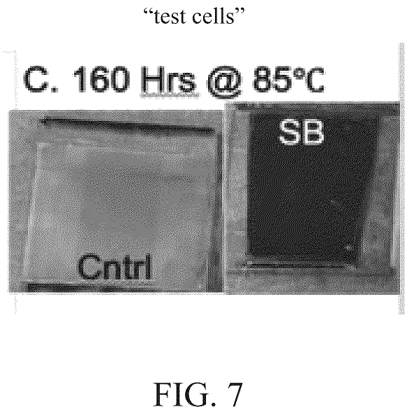

When exposed to the water drop test, bare perovskite degraded and converted from a first black perovskite phase to a second yellow degraded phase containing lead iodide within about 3 to 4 seconds as shown in Table 1 below. However, barrier layers on both test cells and scribed test cells, through iterations of tests and ink formulations, began showing encouraging results. Many different barrier materials and formulations were conceived. However, for many months of testing, barrier materials may have been effective in one test but ineffective in another. Some of the barrier materials (in the form of layers) tested were able to slow the yellowing of the perovskite from the water drop test on the order of seconds to the order of minutes, and many barrier materials were capable of effectively reducing degradation for the light soak test. However, for these initial tests, many of the barrier materials were incapable of significantly reducing degradation due to exposure to heat (85° C. on a hot plate). One exception was CYTOP®, a commercially made fluoropolymer. On its own CYTOP® performed well with all three tests. Notably, however, the combination of a CYTOP® layer with a layer resulting from the application of terpineol and polyethyleneimine (TERPEIE) solution onto the CYTOP® layer (perovskite/CYTOP®/TERPEIE) resulted in a very effective barrier layer combination. The PEIE and CYTOP® were each tested alone and in various combination with each other: PEIE then CYTOP® (one layer of each for a total of two layers), CYTOP® then PEIE, PEIE then CYTOP® then PEIE then CYTOP® (two layers of each for a total of four layers), and CYTOP® then PEIE then CYTOP® then PEIE (a total of four layers). The first discovery of an effective heat barrier is shown in FIG. 7 and was the barrier combination of CYTOP®) and TERPEIE (two layers of each) in the device stack: ITO/PTAA/perovskite/CYTOP®/TERPEIE/CYTOP®/TERPEIE. The combination of two or more barrier layers, e.g., CYTOP® and TERPEIE, is referred to herein as a super barrier (SB). These devices were coated with CYTOP® and TERPEIE by depositing a liquid solution of 10 wt % PEIE in Terpineol onto the CYTOP® and TERPEIE, with the liquid layer subsequently annealed to create a second polymer layer of PEIE on the CYTOP® fluoropolymer layer.

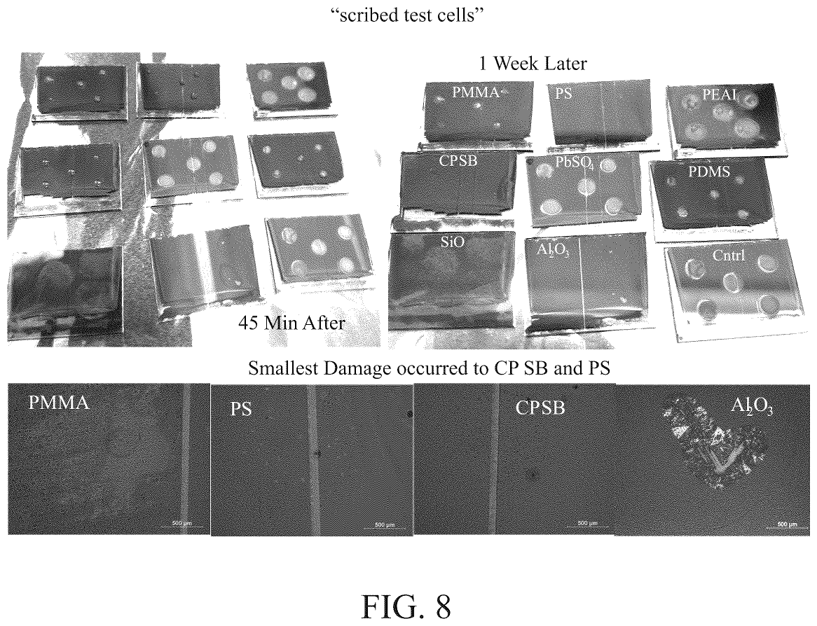

The CYTOP®/TERPEIE SB was extremely effective for all three tests, the water drop test, the heat test, and the light soak test. Water droplets were incapable of completely penetrating the barrier films and surface tension on the outer TERPEIE surface was low enough that the water would slide off the surface when the sample was tilted at approximately 45 degrees. Furthermore, water drops left negligible damage even for the extreme case of letting the water remain on the surface of the device until it had completely evaporated, and the surface was dry. An example from a later experiment of this is shown in FIG. 8. The CYTOP®/TERPEIE SB also performed extremely well when tested under both the heat test and the light soak test. There was visually unnoticeable change to the perovskite sample that was protected by the CYTOP®/TERPEIE SB, even after many hours of both the heat and light soak tests (completed independently and not in series or simultaneously).

In addition to the three stressor tests as mentioned above (heat, light, and water), a fourth test was developed to demonstrate the effectiveness of barrier materials when samples, test cells, scribed test cells, and/or test modules were placed in an environment that was at 85° C. and at 85% relative humidity (RH). This stressor test is referred to herein as the “85/85 test”.

After discovering the success of the CYTOP®/TERPEIE SB, it was determined that CYTOP® may be prohibitively expensive. So, other potential barrier materials were evaluated that could be just as effective as CYTOP®/TERPEIE SB while also being less expensive and more scalable. However, CYTOP®/TERPEIE SB was included in these subsequent studies as a baseline exemplifying an effective barrier. As described herein, eight barrier materials were developed and tested using scribed test cells as illustrated in FIG. 2A, with the important goal of validating their compatibility with the device's perovskite layer, charge transport layers (HTL and ETL), and contact layers. In these initial tests, referring again to FIG. 2A, devices having a structure of the first substrate layer 110 (glass substrate/ITO)−first contact layer 120/PTAA−first CTL 130 (PTAA-HTL)/absorber layer 140 (perovskite)/one or more barrier layers 180, were tested (ITO=indium tin oxide; PTAA=poly(triarylamine) hole transport layer). Before depositing the various barrier layers, each test cell was scribed using at least one of a laser and/or a mechanical scribe, with scribe lines penetrating through the perovskite and HTL to the ITO layer. The eight barrier materials included:
1. Polystyrene (PS);
2. Polydimethylsiloxane (PDMS);
3. Two barrier system of polyethylenimine (PEIE) and CYTOP® (CYTOP®/TERPEIE SB);
4. Polymethylmethacrylate (PMMA);
5. Lead sulphate;
6. phenethylammonium iodide (PEAI);
7. SiOₓ, (0<x≤2); and
8. Al₂O₃.

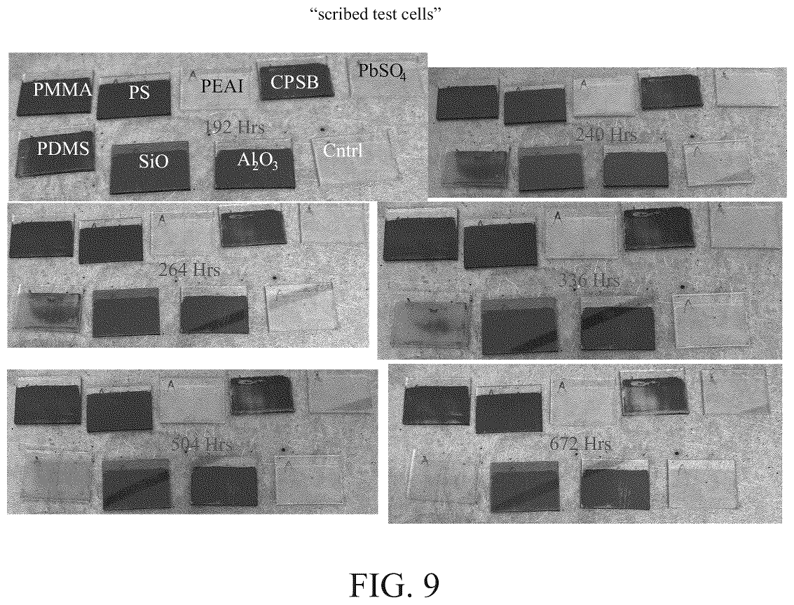

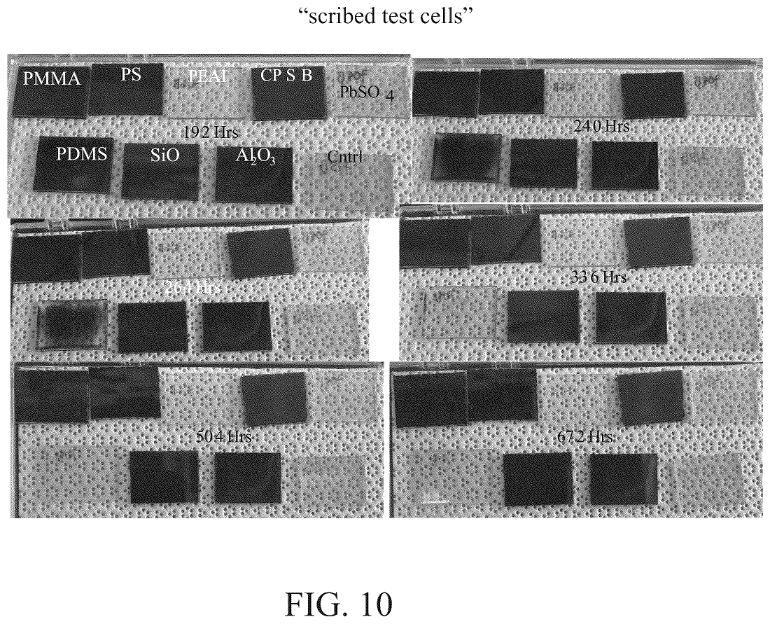

Table 1 below summarizes the eight barrier materials that were tested using scribed test cells, along with each material's thickness and the time endured before perovskite degradation occurred, as indicated by a color change from black to clear, for each of the four tests completed per barrier material. As described above, all the solution processed barriers were deposited by blade-coating and each ink went through optimization experiments to ensure the best film formation for each barrier tested. Table 1 also shows the end results of all the tests and the times for perovskite degradation (as indicated by changing from a dark color to pale yellow or clear) to take place. The results of these barrier tests on the eight different barrier materials against a control are shown in FIGS. 8, 9 and 10, which illustrate photos taken from hours 192 to 627 as a summary of results. Experiments were conducted for a total of 1,176 hours for each material and the results are summarized in Table 1. The results of the four barrier layer tests compared to the perovskite control gave insight into the best barrier materials and identified which materials to down-select for additional testing. Of the barrier materials tested PS, PMMA, PEIE/CYTOP® SB, SiOₓ, and Al₂O₃ were selected to study further on perovskite modules.

TABLE 1
Comparison of the eight barrier materials coated onto perovskite-containing
scribed test cells across four tests per barrier material.

| Barrier | Solution | | | Heat | | Light .7 | | 85° C./ | | Thickness |
|---|---|---|---|---|---|---|---|---|---|---|
| Material | Processable | Water | | 85° C. | | Sun | | 85% H | | (nm) |
| PS | yes | >20 | min | >960 | hrs | 1,176 | hrs | 672 | hrs | 1500 |
| PDMS | yes | ~15 | min | −192 | hrs | 240 | hrs | 168 | hrs | 1000 |
| PEIE/ | yes | >20 | min | −264 | hrs | 1,176 | hrs | 672 | hrs | 2000 |
| CYTOP ® | | | | | | | | | | |
| PMMA | yes | ~20 | min | −600 | hrs | 1,176 | hrs | 1,176 | hrs | 1500 |
| PbSO₄ | yes | 2 | sec | −48 | hrs | 48 | hrs | 48 | hrs | N/A |
| PEAI | yes | 7 | sec | −48 | hrs | 48 | hrs | 48 | hrs | N/A |
| SiOₓ | no | ~5 | min | −1,176 | hrs | 1,176 | hrs | 1,176 | hrs | 1000 |
| Al₂O₃ | no | ~12 | min | −504 | hrs | 1,176 | hrs | 1,176 | hrs | 50 |
| No | N/A | 4 | sec | −48 | hrs | 48 | hrs | 168 | hrs | N/A |
| Barrier | | | | | | | | | | |

Having tested these eight barrier materials in scribed test cells, it was clear that five were better performing than the rest. While the PEIE/CYTOP® SB worked well, cost and complexity issues led to the material's elimination from realistically scaling the product to a commercial level. However, since the combination was very effective the PEIE/CYTOP® SB was included in subsequent testing for comparison to the effectiveness of the other barrier materials. The four barrier materials that not only passed the stressor tests, but are also economical and commercially available are PS, PMMA, SiOₓ, and Al₂O₃. The performances of these barrier materials were then tested further on both perovskite-containing test cells and perovskite-containing test modules to evaluate how they affect solar cell performance, to evaluate if they infill or completely cover the exposed scribes, and to evaluate their optical properties.

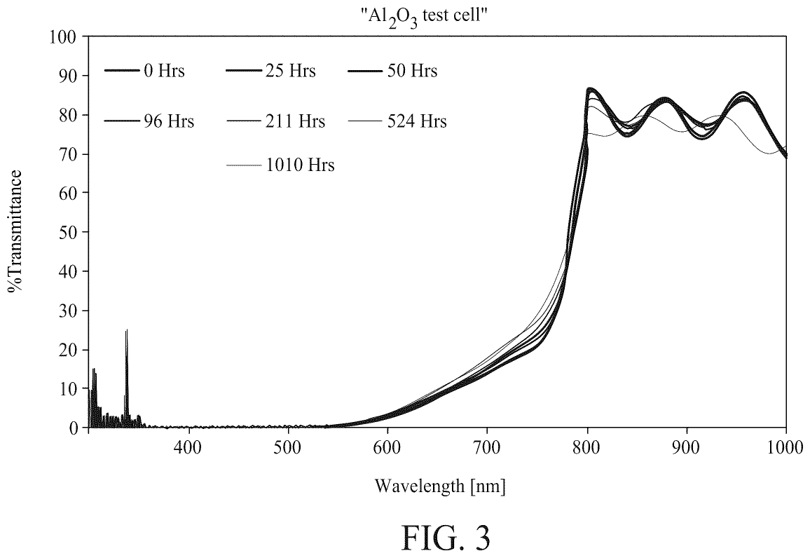

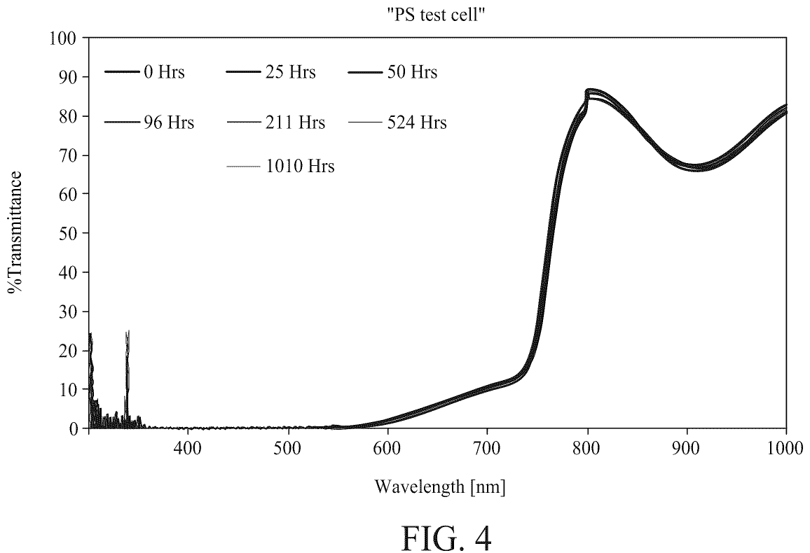

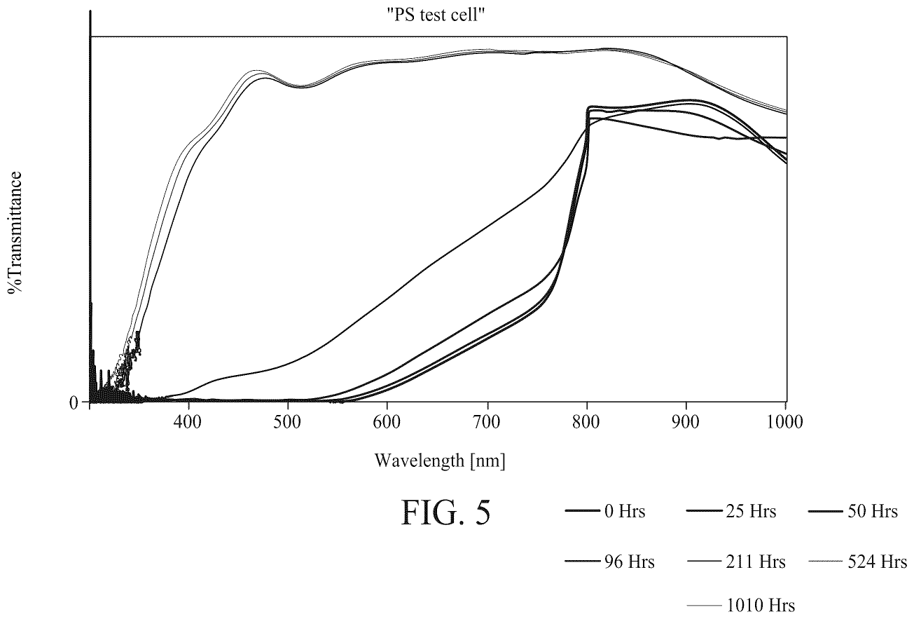

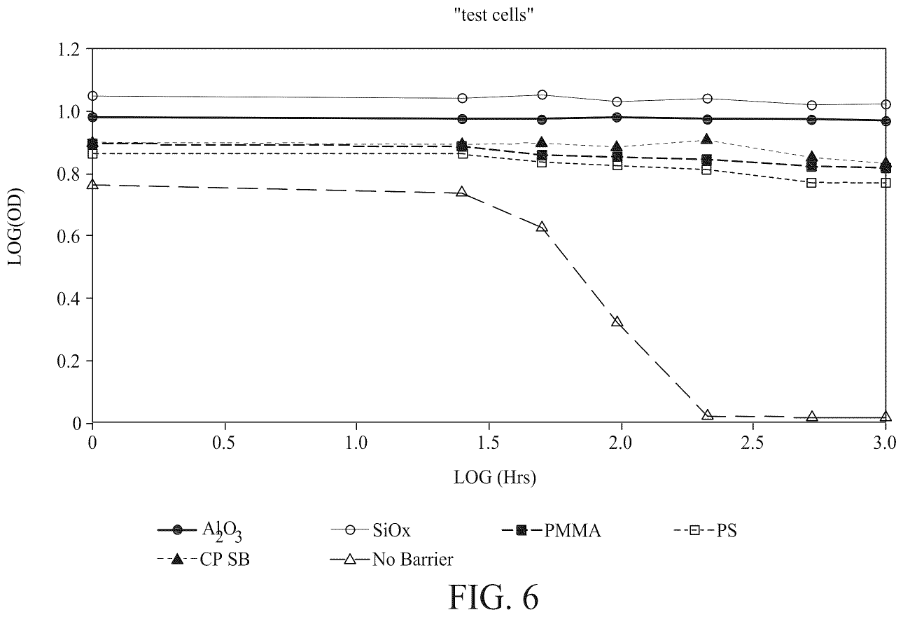

To gain a more qualitative understanding of the differences in barrier material effectiveness, a new experiment was conducted using percent optical transmittance data on a new set of test stacks (see FIG. 1B) that compared the now five most successful barrier materials to an uncoated test stack. FIGS. 3-6 illustrate experimental results obtained from these experiments. These tests included, first a control perovskite, without a protective barrier layer, and then device stacks with perovskite layers covered with various barrier layer materials; Al₂O₃, SiOₓ, PMMA, PS, or CYTOP®/TERPEIE. Each device stack tested had the following architecture: glass substrate−first substrate layer 110/ITO−first contact layer 120/PTAA−first charge transport layer 130 (HTL)/absorber layer 140 (perovskite)/one or more barrier layers 180. Ultraviolet-visible (UV-VIS) percent transmission data was taken to quantify the effectiveness of this barrier layer. Each data set was taken periodically between an elapsed time of 0 hours to 1010 hours. FIGS. 3-6 clearly illustrate with UV-VIS, what can be seen visually in FIGS. 7, 8, 9, and 10 from the previous experiments; that the control perovskite (no protective barrier layer) after 96 hours under 0.7 AM1.5 suns completely converted to a nearly transparent film, whereas the perovskites covered with the Al₂O₃, SiOₓ, PMMA, PS, and CYTOP®/TERPEIE did not change phases and maintained their perovskite crystalline phase. To quantify the change, the optical density at 700 nm and the absolute value of the change in percent transmission was calculated comparing the original percent transmission scan to after 1010 hours under 0.7 AM1.5 suns in ambient. These values are displayed in Table 2 and suggest that the barrier layers reduced the degradation of the perovskite by orders of magnitude with the most improvement demonstrated by the alumina and silicon oxide barrier layers. (Decay constants Σ(Abs(Δ% T)) equal to zero indicate no decay.)

TABLE 2
Barrier layer results for unscribed test cells from FIGS. 3-6

| | Decay | Improvement | | Improvement |
|---|---|---|---|---|
| Material | Constant | on Control | Σ(Abs(Δ% T)) | on Control |
| Al₂O₃ | −0.0031 | 98.4 | 711.58 | 53.57 |
| SiOₓ | −0.01 | 30.5 | 651.25 | 58.53 |
| PMMA | −0.0265 | 11.5 | 1867.16 | 20.41 |
| PS | −0.0351 | 8.7 | 1908.79 | 19.97 |
| CP SB | −0.0177 | 17.2 | 1570.3 | 24.27 |
| No barrier | −0.03051 | 1.0 | 38115.87 | 1.0 |

Test modules were tested next. Each of the layers within a perovskite module are susceptible to degradation due to the interaction with the barrier material or its solvent, so the barrier layers described herein are not just important from the perspective of the perovskite layer but may also be important for preserving other layers in a perovskite-containing solar cell and/or module. Perovskite test modules were built on 1 inch by 3 inch substrates (ITO sputtered onto glass). Selected barrier materials were then blade coated onto perovskite test modules and inspected for degradation. Most importantly, the PCE of the test modules, using modules with a PCE floor of 10%, had to maintain within 1% (absolute) of the starting efficiency (for example, 12% module must be above 11% after coating). The stacks were then investigated by optical microscopy, optical profilometry, scanning electron microscopy (SEM), stylus profilometry, and JV scans under solar simulation. Stylus and optical profilometry, as well as SEM, were used to investigate the third scribe line P3 and a fourth scribe line P4 and confirmed they were filled with the barrier materials with more than the minimum thickness of 50 nm. Optical constants were measured by ellipsometry to identify the optical constants of the barrier films.

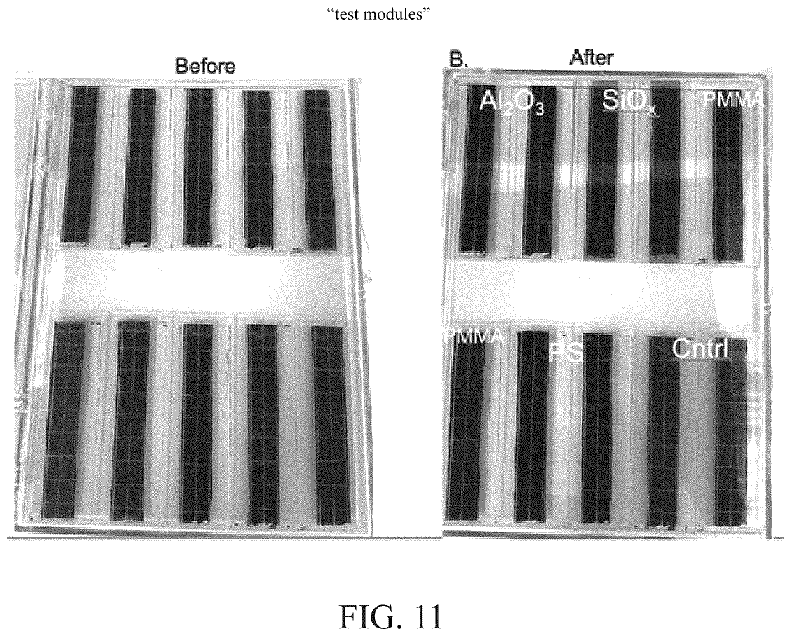

A goal of these studies was to identify a satisfactory barrier layer and/or or combination of barrier layers for coated perovskite solar cells capable of maintaining their original PCEs within 1% of the performance of the original uncoated perovskite devices. To satisfy this requirement, two separate batches were manufactured of ten 1×3″ IZO, semi-transparent modules with seven submodules. Each submodule had two cells connected in series by a third scribe line P3 as shown in FIG. 2B. Each submodule was tested individually for a total of 70 submodules tested. One of the two batches of 10 modules (70 submodules) tested is shown as illustrated in FIG. 11. These 10 modules were then aged five days. On the fifth day, all the barrier materials were applied to their respective modules. However, before any barrier layer treatment was applied, all ten modules (70 submodules) were measured for pre-deposition measurements. After the initial testing was completed, the barrier materials were applied. Two modules were blade coated with PS, and two modules were blade coated with PMMA. Two modules were coated with Al₂O₃ having a thickness of about 50 nm by atomic layer deposition (ALD). Two modules were coated with SiOₓ having a thickness of 1000 nm of SiOₓ by thermal evaporation. The last two modules were left uncoated without a barrier material to be measured as a control. The two control modules remained in the same container as the blade coated modules to experience the same ambient environment through the process. After all the modules were coated with their respective barrier materials, they were all measured again for post-deposition performance.

FIG. 11 illustrates photographs of test modules before and after the deposition of the barrier materials. Each module included both vertical scribes and horizontal scribes. The vertical scribes are the previously mentioned first scribe line P1, second scribe line P2, and third scribe line P3, used to connect two solar cells electrically in series to create a submodule. The horizontal scribes are referred to herein as a fourth scribe line P4 and divide each module substrate into seven submodules. It is important to note that there was no visible degradation to any of the scribe lines after the application of the respective barrier materials. Further, FIG. 11 only shows a first batch of modules that were tested. An entire second batch was also made to show repeatability for a total of 20 modules tested, 4 modules per treatment.

Next, the PCE of each submodule was evaluated to determine any degradation in the values when comparing post-barrier-layer-deposition PCE to the modules' pre-deposition performance. Table 3 below shows the truncated version of the JV scan data for before and after the barrier layer depositions on the modules. Table 3 shows the averages before and after each barrier material deposition. For the first batch, both PS and SiOₓ had no influence on the PCE, whereas a PMMA layer reduced the PCE by 0.43% and Al₂O₃ layer reduced the PCE by 0.97%. In the second batch, the only change that was made was the Al₂O₃ deposition temperature was reduced from 60° C. to 50° C., which also reduced the loss in PCE performance from a loss of 0.97% to a loss of 0.74%. The second batch showed that all PMMA, PS, and SiOₓ resulted in no changes in performance with each change being within measurement errors. Table 3 summarizes that the barrier materials PS, PMMA, SiOₓ, and Al₂O₃ all affect the module performance by less than 1% PCE. Furthermore, the performance averages of each of the modules were well above the 10% PCE floor requirement.

TABLE 3
Scan statistics before and after each type of barrier material deposition for two batches of 10 modules each.
BATCH 2

| Before Al2O3 | | | | | Before SiOx | | | | | Before PMMA | | |
|---|---|---|---|---|---|---|---|---|---|---|---|---|
| | PCE | [symbol] | [symbol] | [symbol] | | PCE | [symbol] | [symbol] | [symbol] | | PCE | [symbol] |
| | Before | Before | Before | Before | | Before | Before | Before | Before | | Before | Before |
| Average | 14.01 | [symbol] | 2.30 | 66.91 | Average | 13.51 | 9.01 | [symbol] | [symbol] | Average | 13.63 | 9.07 |
| After Al2O3 | | | | | After SiOx | | | | | After PMMA | | |
| | PCE | [symbol] | [symbol] | [symbol] | | PCE | [symbol] | [symbol] | [symbol] | | PCE | [symbol] |
| | After | After | After | After | | After | After | After | After | | After | After |
| Average | 13.27 | 9.12 | 2.27 | [symbol] | Average | [symbol] | 8.96 | 2.31 | [symbol] | Average | [symbol] | 9.06 |
| Change | −0.74 | 0.01 | −0.02 | [symbol] | Change | 0.07 | −0.04 | [symbol] | [symbol] | Change | −0.02 | −0.01 |
| | BATCH 2 | | | | | | | | | | | |
| | Before PMMA | | Before PS | | | | | Before Control | | | | |
| | [symbol] | [symbol] | | PCE | [symbol] | [symbol] | [symbol] | | PCE | [symbol] | [symbol] | [symbol] |
| | Before | Before | | Before | Before | Before | Before | | Before | Before | Before | Before |
| | 2.31 [symbol] | [symbol] | Average | [symbol] | 9.13 | 2.30 | 64.60 | Average | 13.80 | 9.15 | [symbol] | 65.87 |
| | After PMMA | | After PS | | | | | After Control | | | | |
| | [symbol] | [symbol] | | PCE | [symbol] | [symbol] | [symbol] | | PCE | [symbol] | [symbol] | [symbol] |
| | After | After | | After | After | After | After | | After | After | After | After |
| | 2.30 | [symbol] | Average | [symbol] | 9.12 | 2.29 | [symbol] | Average | 13.78 | 9.17 | [symbol] | [symbol] |
| | −0.01 | 0.12 | Change | 0.07 | −0.01 | −0.01 | [symbol] | Change | −0.03 | 0.02 | 0.00 | −0.35 |

BATCH 1

| Before Al2O3 | | | | | Before SiOx | | | | | Before PMMA | | |
|---|---|---|---|---|---|---|---|---|---|---|---|---|
| | PCE | [symbol] | [symbol] | [symbol] | | PCE | [symbol] | [symbol] | [symbol] | | PCE | [symbol] |
| | Before | Before | Before | Before | | Before | Before | Before | Before | | Before | Before |
| Average | 13.92 | 9.39 | 2.29 | 64.64 | Average | 14.70 | 9.47 | 2.31 | 67.14 | Average | 14.27 | [symbol] |
| After Al2O3 | | | | | After SiOx | | | | | After PMMA | | |
| | PCE | [symbol] | [symbol] | [symbol] | | PCE | [symbol] | [symbol] | [symbol] | | PCE | [symbol] |
| | After | After | After | After | | After | After | After | After | | After | After |
| Average | 12.96 | 9.32 | [symbol] | 61.53 | Average | 14.65 | [symbol] | 2.31 | [symbol] | Average | 13.84 | 9.38 |
| Change | −0.97 | −0.07 | −0.04 | −3.11 | Change | −0.05 | 0.02 | 0.00 | −0.42 | Change | −0.43 | 0.03 |
| | BATCH 1 | | | | | | | | | | | |
| | Before PMMA | | Before PS | | | | | Before Control | | | | |
| | [symbol] | [symbol] | | PCE | [symbol] | [symbol] | [symbol] | | PCE | [symbol] | [symbol] | [symbol] |
| | Before | Before | | Before | Before | Before | Before | | Before | Before | Before | Before |
| | 2.31 | [symbol] | Average | 14.24 | 9.38 | 2.28 | [symbol] | Average | 14.35 | 9.31 | 2.28 | 67.50 |
| | After PMMA | | After PS | | | | | After Control | | | | |
| | [symbol] | [symbol] | | PCE | [symbol] | [symbol] | [symbol] | | PCE | [symbol] | [symbol] | [symbol] |
| | After | After | | After | After | After | After | | After | After | After | After |
| | 2.30 | [symbol] | Average | 14.32 | 9.48 | 2.28 | [symbol] | Average | [symbol] | 9.54 | 2.29 | [symbol] |
| | [symbol] | [symbol] | Change | 0.08 | [symbol] | 0.00 | −0.23 | Change | 0.26 | 0.23 | [symbol] | [symbol] |

[symbol]

indicates data missing or illegible when filed

The next goal was to show that the barrier materials tested are in contact with the scribe walls by either fully filling the third scribe line P3 and the fourth scribe line P4 or by providing a layer of the material at least 50 nm thick coating the walls inside the scribes. Optical microscopy and optical profilometry were insufficient methods to prove the infill of the scribe because both methods were imaging through the material. Stylus profilometry was also insufficient to prove an infill of scribes because the coated layers followed a similar geometry of the scribe since all the barrier layers were blanket coated. The best method for validating infill and complete scribe wall passivation was cross sectional SEM.

FIGS. 12A, 12B, and 12C illustrate SEM images of the four exemplary barrier materials inside second scribe line P2 and third scribe line P3 of four test modules. These four images show each barrier material completely covered the sidewalls of the scribe, therefore, no perovskite is exposed. Panel A of FIG. 12 illustrates that the Al₂O₃ did not fill the scribe but maintained a precise thickness and film uniformity around the edges and surfaces of the scribe. Panels B, C, and D of FIG. 12 illustrate PMMA, PS, and SiOₓ, respectively. Each of these three barrier materials completely filled the scribe and encased the surfaces of the scribe sidewall with the barrier material. Furthermore, each of the barrier layer films in the SEM images maintained uniformity around the scribe corners to provide no ingress or egress. The behavior and quality of the films displayed below are representative of their behavior and quality throughout the entire 1 inch by 3 inch module substrate. FIG. 12B illustrates an enlarged version of an SEM image of a submodule stack (as shown in FIG. 2B) with the layers designated. The HTL and CTL are too thin to recognize. The SEM images in FIG. 12C shows the entire width of the third scribe line P3 and provides evidence that the scribes have been fully encased in their respective barrier materials.

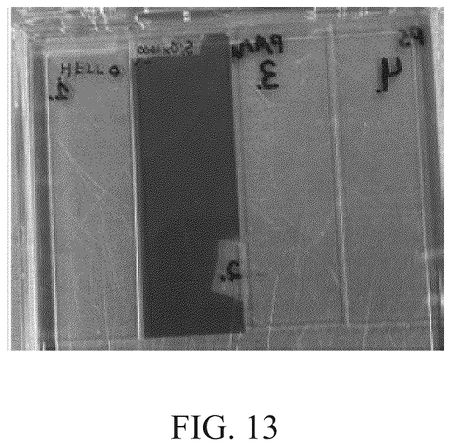

It has been shown herein that the barrier films do not affect PCE performance beyond 1%, and that the barrier films completely encase the exposed perovskite in module scribes. The optical properties of the barrier films were evaluated next. Ellipsometry measurements were taken to understand the barrier films' refraction index, n, and extinction coefficient, k. Films were blade-coated on blank 1″×3″ microscope slides, with an additional blank microscope slide being used as the substrate baseline for the n and k calculations. FIG. 13 illustrates the four exemplary barrier materials on blank glass microscope slides. From left to right the barrier layers are Al₂O₃, SiOₓ, PMMA, and PS. Aside from SiOₓ, all barriers are transparent. Table 4 summarizes the calculated n and k values from ellipsometry measurements using the Cauchy model for Al₂O₃, the Cody Lorentz model for SiOₓ, the Cauchy model for PMMA, and the GenOsc model for PS. The values shown in Table 4 represent the values at wavelength 371 nm and at 1596 nm. A steady and gradual change between these values occurs within the wavelengths 372 nm to 1595 nm and are within range of the listed values. The ellipsometry measurement calculations of n and k show that SiOₓ has the highest refraction index and extinction coefficient.

TABLE 4
The calculated values of the refraction
index, n, and extinction coefficient, k.
Ellipsometry n and k Calculations

| Barrier | n (371 nm to 1596 nm) | k (371 nm to 1596 nm) |
|---|---|---|
| Al₂O₃ | 1.621-1.586 | 0.0085 |
| SiOₓ | 2.166-1.826 | 0.256-0.0040 |
| PMMA | 1.501-1.484 | 0.0735-0.0212 |
| PS | 1.638-1.570 | 0.000-0.000 |

### Photovoltaic Processing Sequence Example

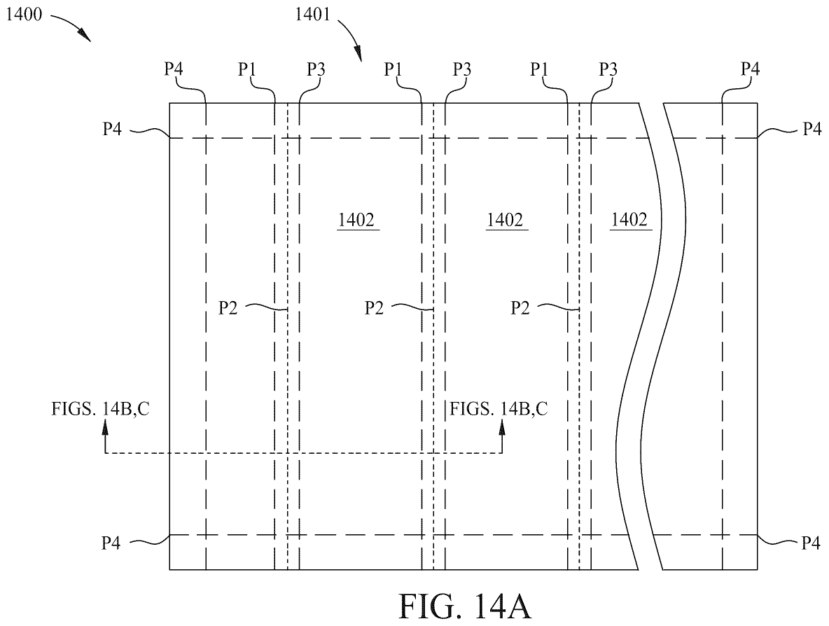

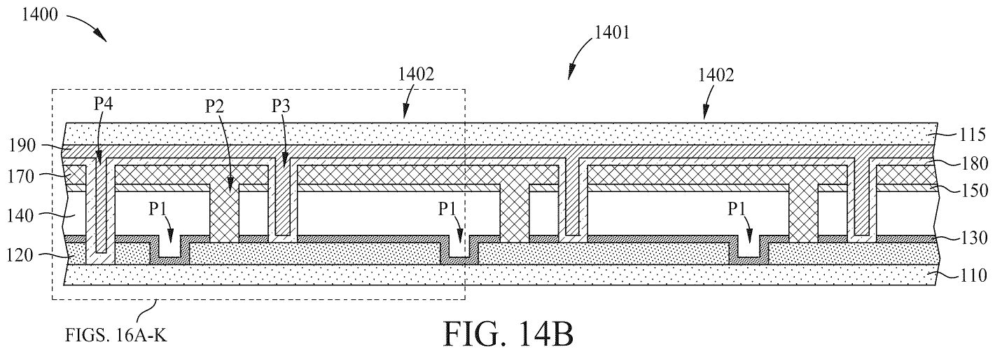

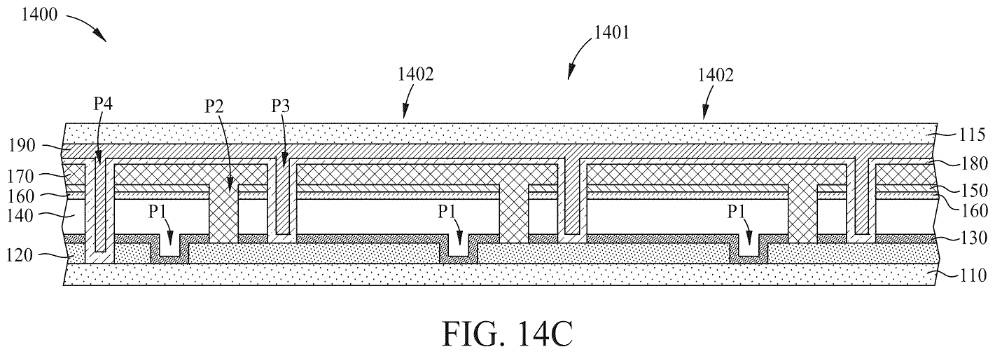

FIG. 14A illustrates a schematic plan view of a photovoltaic assembly 1400 that includes a photovoltaic device array 1401. The photovoltaic device array 1401 includes a plurality of series connected photovoltaic devices 1402. The photovoltaic device array 1401 includes a plurality of features, such as a plurality of first scribe lines P1, a plurality of second scribe lines P2, and a plurality of third scribe lines P3 that are used to form the series connected photovoltaic devices 1402, and a plurality of fourth scribe lines P4 that are used to separate and isolate the series connected photovoltaic devices 1402 from the edge regions of the photovoltaic assembly 1400. As illustrated in FIG. 14A, the fourth scribe lines P4 surround the photovoltaic device array 1401.

FIG. 14B illustrates a schematic side cross-sectional view of a portion of the photovoltaic device array 1401, which includes a sectioned portion of the photovoltaic device array 1401 formed by the sectioning line 14B-14B shown in FIG. 14A. The sectioned portion of the photovoltaic device array 1401 shown in FIG. 14B illustrates a configuration of a plurality of features, such as the first scribe line P1, the second scribe line P2, the third scribe line P3, and the fourth scribe line P4, as described further below. The photovoltaic device array 1401, shown in FIG. 14B, includes a first substrate layer 110, a first contact layer 120, a first charge transport layer 130, an absorber layer 140, a second charge transport layer 150, a second contact layer 170, a plurality of features, one or more barrier layers 180, an encapsulation layer 190, and a second substrate layer 115.

FIG. 14C illustrates a schematic side cross-sectional view of a portion of an alternately configured photovoltaic device array 1401, which includes a sectioned portion of the photovoltaic device array 1401 formed by the sectioning line 14C-14C shown in FIG. 14A. The sectioned portion of the photovoltaic device array 1401 shown in FIG. 14C illustrates a configuration that includes an alternate photovoltaic device stack which similarly includes the plurality of features illustrated and described in relation to FIG. 14B. The photovoltaic device array 1401, shown in FIG. 14C, additionally includes a buffer layer 160 that can be disposed between the absorber layer 140 and second charge transport layer 150, or the second charge transport layer 150 and the second contact layer 170.

While not intending to be limiting as to the scope of the disclosure provided herein, and for ease of discussion purposes, the following discussion will primarily discuss a photovoltaic device array 1401 that is configured to include photovoltaic device stack illustrated in FIG. 14C. However, other photovoltaic device stack configurations, such as the photovoltaic device stack illustrated in FIG. 14B, can also benefit from the various embodiments of the disclosure provided herein.

### Photovoltaic Device Stack Configuration

In some embodiments, a photovoltaic device stack includes a first substrate layer 110, a first contact layer 120, a first charge transport layer 130, an absorber layer 140, a second charge transport layer 150, a buffer layer 160, a second contact layer 170, a plurality of features, one or more barrier layers 180, an encapsulation layer 190, and a second substrate layer 115. In one configuration, as shown in FIG. 14C, the buffer layer 160 is disposed between absorber layer 140 and the second charge transport layer 150, but other photovoltaic device stack configurations can benefit from the disclosure provided herein.

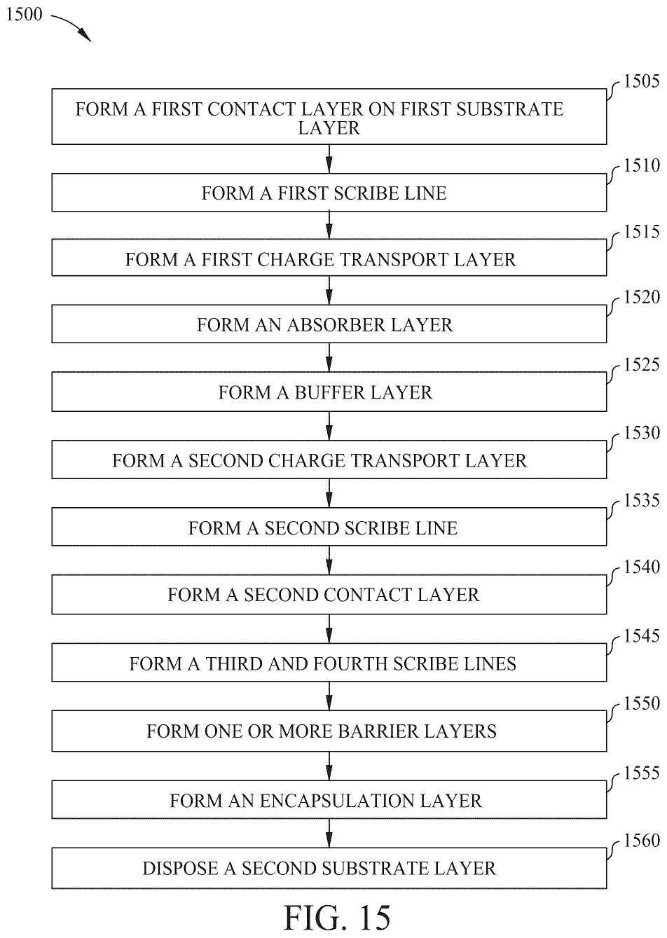

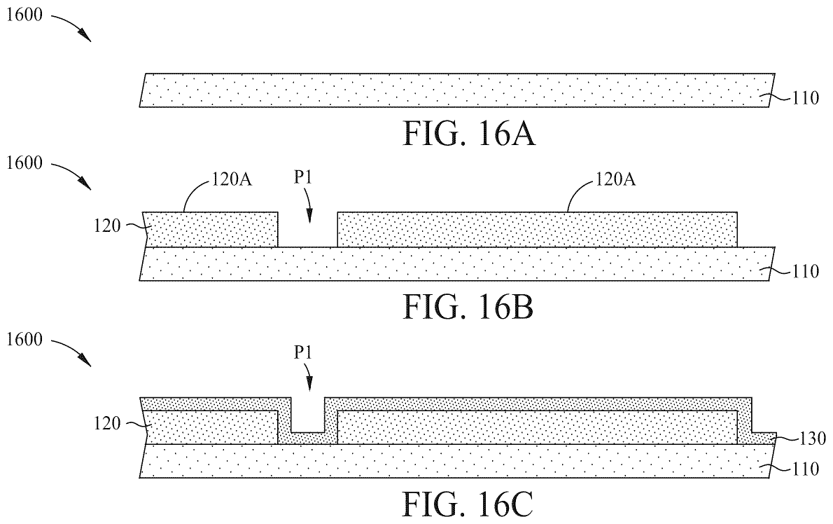

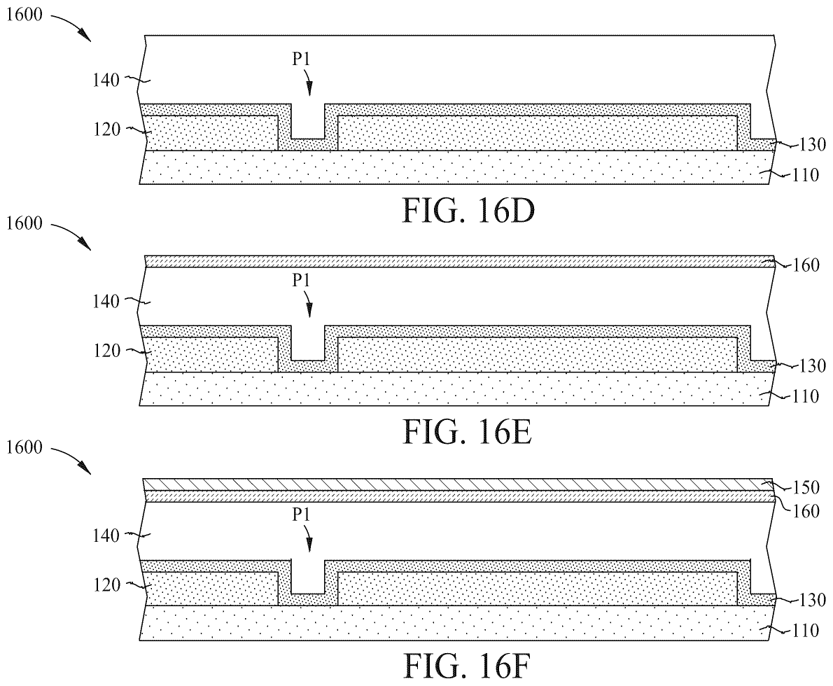

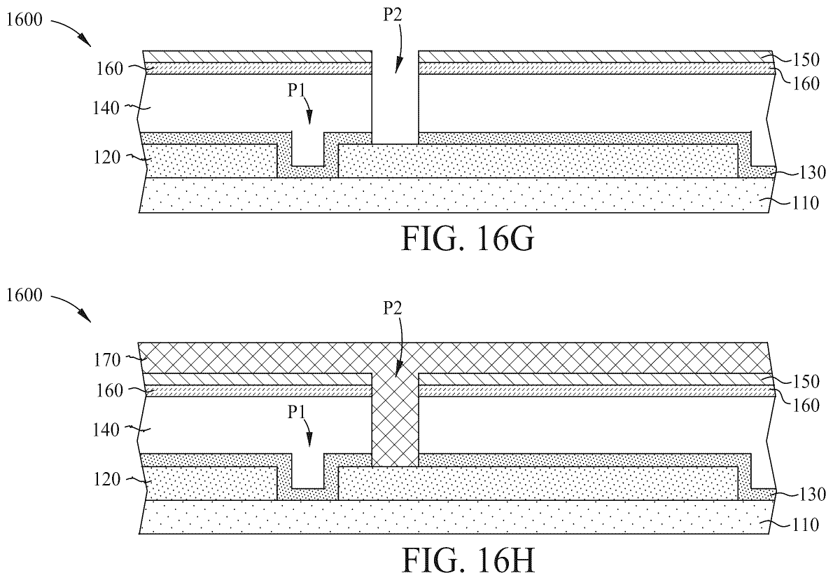

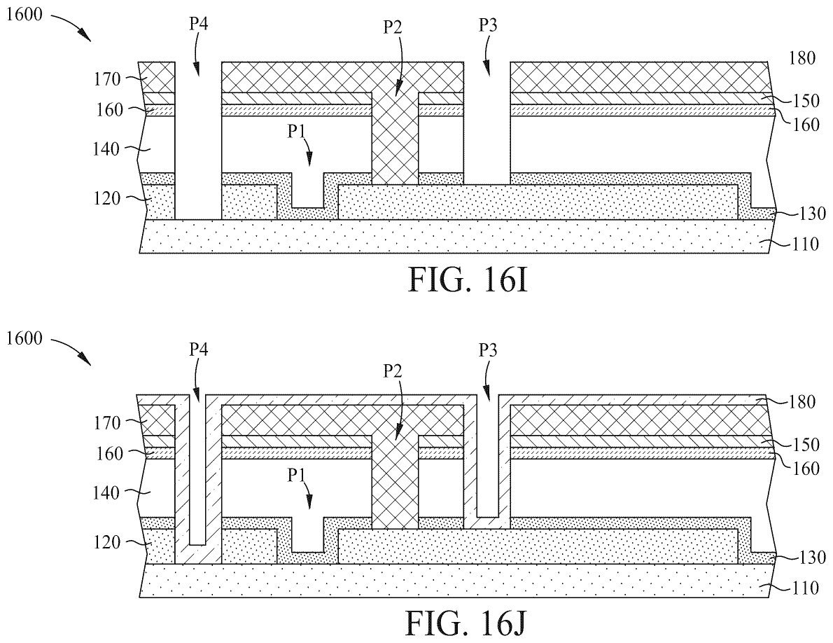

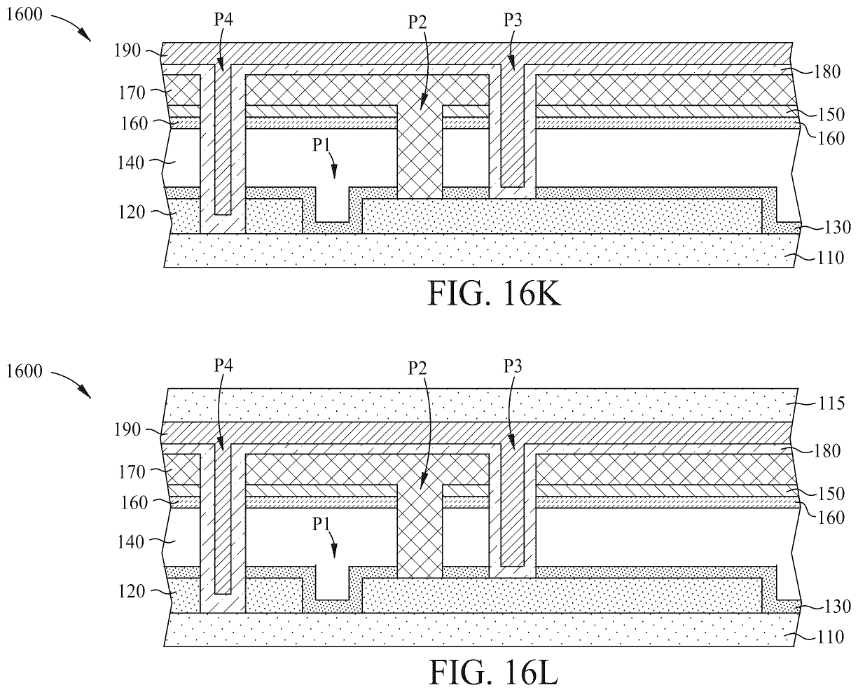

FIG. 15 illustrates a method 1500 of fabricating a photovoltaic device stack within the photovoltaic assembly 1400 according to one or more embodiments of the present disclosure. FIGS. 16A-16L illustrate schematic cross-sectional views of the photovoltaic device stack during various stages of the fabrication of the photovoltaic assembly 1400 which relate to the operations found in method 1500 illustrated in FIG. 15.

Referring to FIG. 16A, the photovoltaic device stack includes a first substrate layer 110. The first substrate layer 110 has a first substrate thickness between about 50 μm to about 10 mm. In some embodiments, as discussed above, the first substrate layer 110 can include one or more materials selected from a group that includes a metal foil, silicon, glass, and/or a polymer substrate. In some embodiments, the first substrate layer 110 can include glass with a thickness between about 1 and 5 mm, more preferably between 2 and 3.2 mm. In some embodiments, the first substrate layer 110 can include metal foil and/or a polymer with a thickness between about 50 μm and 500 μm, more preferably between 40 μm and 150 μm. The first substrate layer 110 can include a roughened surface on which the various layers of the photovoltaic device stack are to be formed, wherein the roughened surface has a peak-to-valley roughness between about 1 nm to about 10 μm. For example, a peak-to valley roughness is about 1 micrometer (μm).

As illustrated in FIG. 16B, at operation 1505 of the method 1500, a first contact layer 120 is formed on a first surface of the first substrate layer 110. The first contact layer 120 includes an electrical contact layer material. The electrical contact layer material may include any suitable material, including, but not limited to, copper, silver, gold, indium tin oxide (ITO), fluorine doped tin oxide (FTO), or any combination thereof. In some embodiments, the first contact layer 120 may have include one or more layers, where each layer of the plurality of layers includes a contact layer material, such as a transparent conductive oxide layer. The first contact layer 120 can have a first contact thickness between about 5 nanometers (nm) to about 1000 nm. The first contact layer 120 may be formed by any suitable process including, but not limited to a physical vapor deposition (PVD) process (e.g., sputtering or evaporation processes), a chemical vapor deposition (CVD) process, plasma enhanced chemical vapor deposition (PECVD) process, an atomic layer deposition (ALD) process, a plasma enhanced atomic layer deposition (PEALD) process, or other suitable deposition technique.

At operation 1510, as shown in FIG. 16B, the first contact layer 120 is patterned by performing a first scribing process in which the first scribe lines P1 are formed in the first contact layer 120. The first scribe lines P1 are formed so that each P1 scribe extends through the first contact layer 120 and at least to the surface of the first substrate layer 110 to form electrically isolated regions 120A that include portions of the first contact layer 120. As shown in FIG. 16B, the first scribe line P1 divides the first contact layer 120 into two separate electrically isolated regions 120A. The first scribe line P1 may be formed by any suitable process, including, but not limited to, mechanical scribing systems, laser ablation, or combination thereof.

As shown in FIG. 16C, at operation 1515, a first charge transport layer (CTL) 130 is formed over the patterned first contact layer 120. The first CTL 130 is disposed over the patterned portions of the first contact layer 120, the exposed sidewall surfaces of the first scribe lines P1, and the exposed portion of the first substrate layer 110. The first CTL 130 has a first CTL thickness between about 0.1 nm to about 10 μm, preferably between about 1 to 100 nm, more preferably between 10 to 70 nm. The first CTL 130 may be formed by any suitable process including, but not limited to a chemical vapor deposition (CVD) process, plasma enhanced chemical vapor deposition (PECVD) process, an atomic layer deposition (ALD) process, a plasma enhanced atomic layer deposition (PEALD) process, a physical vapor deposition (PVD) process (e.g., evaporation process), or other suitable deposition technique.

In some embodiments, the first CTL 130 may be configured to act as a hole transport layer (HTL) including a hole transport material, or to act as an electron transport layer (ETL) including an electron transport material. In some embodiments, the first CTL 130 may include a plurality of layers, where each layer of the plurality of layers may include a different material dependent upon the configuration (e.g., HTL versus ETL) of the first CTL 130. The first CTL 130 is an HTL that includes, but are not limited to, PTAA, Poly-TPD, nickel oxide, molybdenum oxide, OMATD, self-assembled monolayers (SAM), or combination thereof. As discussed above, in some embodiments, the first CTL 130, being configured to act as an HTL, may include a plurality of layers where each layer of the plurality of layers may include a different hole transport material.

At operation 1520, as shown in FIG. 16D, an absorber layer 140 is formed over the first CTL 130. In some embodiments, the absorber layer 140 is disposed on the first CTL 130. The absorber layer 140 includes an absorber material, the absorber material may include, a perovskite material, which is described above. In one example, the absorber layer includes a perovskite material that has the stoichiometry of ABX₃, where A is a first cation, B is a second cation, and X comprises at least one halide (e.g., chloride, bromide, or iodide). In another example, the absorber layer 140 includes a perovskite that has a stoichiometry of ABX₃, where A comprising at least one of formamidinium (FA), methylammonium (MA), or cesium, and B comprises at least one of tin or lead, and X comprises at least one halide, methylammonium lead tri-iodide (MAPbI₃), cesium formamidinium methylammonium lead tri-iodide (CsFAMAPbI₃), silicon (amorphous and/or crystalline), Group III-V materials (amorphous and/or crystalline), organic photovoltaic materials (OPV), dye-sensitized solar cells (DSSX), copper indium gallium selenide (CIGS), cadmium telluride (CdTe), or combinations thereof. The absorber layer 140 may be formed by any suitable solution based deposition process including, but not limited to printing, slot-die coating, spray-coating, gravure printing, or any combination thereof.

The deposited absorber layer 140 has an absorber layer thickness between about 300 nm to about 1000 nm. For example, the absorber thickness is between about 450 nm to about 950 nm, preferably between about 500 nm to about 650 nm. In some embodiments, the absorber layer 140 may have an absorber thickness between about 1000 nm to about 2000 nm.

At operation 1525, in some embodiments, a buffer layer 160 is formed over the absorber layer 140. As shown in FIG. 16E, in some cases, the buffer layer 160 is disposed or formed directly on the absorber layer 140. The buffer layer 160 has a first buffer layer thickness between about 0.1 nm to about 20 nm. The buffer layer 160 can comprise a material with a bandgap typically larger than the absorber layer 140 which may passivate the perovskite surface and/or slow the surface recombination rate, create a tunneling barrier, and/or otherwise change the interfacial properties between absorber layer 140 and second charge transport layer 150. Due to the material properties and position of the buffer layer 160 within the photovoltaic device, which in general is between the absorber layer 140 the second contact layer 170, the buffer layer 160 is able to perform these various device enhancing functions and thus improve the performance of the photovoltaic device. The buffer layer 160 can comprise, but is not limited to, oxides, oxysalts, sulfates, organics, organic salts, and fluorides. The buffer layer 160 may be formed by any suitable process including, but not limited to a solution based deposition process, a chemical vapor deposition (CVD) process, plasma enhanced chemical vapor deposition (PECVD) process, an atomic layer deposition (ALD) process, a plasma enhanced atomic layer deposition (PEALD) process, a physical vapor deposition (PVD) process (e.g., evaporation process), or other suitable deposition technique. In one example, the deposited buffer layer 160 has a total thickness between about 0.4 nm to about 40 nm.

At operation 1530, as shown in FIG. 16F, a second charge transport layer (CTL) 150 is deposited over the buffer layer 160 and absorber layer 140. However, as noted above, in some embodiments the second charge transport layer (CTL) 150 is formed over the absorber layer 140 before the buffer layer 160 is formed over the absorber layer 140, and thus the second charge transport layer (CTL) 150 is disposed between the buffer layer 160 and the absorber layer 140. The second CTL 150 may be configured to act as a hole transport layer (HTL) including a hole transport material, or to act as an electron transport layer (ETL) including an electron transport material. In some embodiments, the second CTL 150 may include a plurality of layers, where each layer of the plurality of layers may include a different material dependent upon the configuration (e.g., HTL versus ETL) of the second CTL 150. In one example, the second CTL 150 is an ETL that includes, but is not limited to, a metal oxide such as at least one of TiO₂, SnO₂, Al₂O₃, ZnO, or carbon contacts such as carbon nanotubes, fullerenes (e.g., C₆₀ and or C₇₀), a fullerene derivative [6,6]-phenyl-C₆₁-butyric acid methyl ester (PCBM), or fullerenes used alone or in conjunction with bathocuproine (BCP) or SnO₂, or other metal oxide, or combination thereof. As discussed above, in some embodiments, the second CTL 150, being configured to act as an ETL, may include a plurality of layers where each layer of the plurality of layers may include a different electron transport material. The second CTL 150 has a second CTL thickness between about 0.1 nm to about 1 μm. The second CTL 150 may be formed by any suitable process including, but not limited to vacuum evaporation, atomic layer deposition, sputtering, chemical vapor deposition, or combination thereof.

At operation 1535, as shown in FIG. 16G, a plurality of second scribe lines P2 are formed through the first CTL 130, absorber layer 140, buffer layer 160 and second CTL 150, and expose a portion of the first contact layer 120. In some embodiments, each of the formed second scribe lines P2 may extend into a portion of the first contact layer 120. The second scribe lines P2 each include a surface that contains portions of the second CTL 150, buffer layer 160, a portion of the absorber layer 140, a portion of the first CTL 130, and a portion of the first contact layer 120. The second scribe lines P2 may be formed by any suitable process, including, but not limited to, mechanical scribing systems, laser ablation, or combination thereof.

At operation 1540, as shown in FIG. 16H, a second contact layer 170 is formed over the second CTL 150, buffer layer 160, absorber layer 140, first CTL 130, the first contact layer 120 and the first substrate layer 110. The second contact layer 170 is disposed over the second CTL 150 and fills at least a significant portion or all of the second scribe line P2. The second contact layer 170 may be formed from any suitable contact layer material as described above. In one example, the second contact layer 170 includes an IZO or ITO layer. The second contact layer 170 has a first thickness of between about 5 nm to about 1000 nm. The second contact layer 170 may be formed by any suitable process including, but not limited to a chemical vapor deposition (CVD) process, plasma enhanced chemical vapor deposition (PECVD) process, an atomic layer deposition (ALD) process, a plasma enhanced atomic layer deposition (PEALD) process, a physical vapor deposition (PVD) process, printing, spraying or other suitable deposition technique.

At operation 1545, as shown in FIG. 16I, a plurality of third scribe lines P3 and a plurality of fourth scribe lines P4 are formed through portions of the photovoltaic device stack. Each of the third scribe lines P3 extends through the second contact layer 170, the second CTL 150, and at least a significant portion of the absorber layer 140. In some embodiments, the third scribe lines P3 extends through the second contact layer 170, the second CTL 150, the absorber layer 140, and the first CTL 130, and expose a portion of the first contact layer 120. In some embodiments, the third scribe line P3 may extend into a portion of the first contact layer 120. The third scribe lines P3 each include a surface that contains portions of the second contact layer 170, the second CTL 150, the buffer layer 160, the absorber layer 140, the first CTL 130, and the first contact layer 120. The third scribe lines P3 may be formed by any suitable process, including, but not limited to, mechanical scribing systems, laser ablation, or combination thereof. In some examples of the present disclosure, the third scribe lines P3 and the fourth scribe lines P4 may each have a width between 5 μm and 200 μm.

During operation 1545, a plurality of fourth scribe lines P4 are formed through the device layer stack. The fourth scribe lines P4, extends through the second contact layer 170, the second CTL 150, the absorber layer 140, the first CTL 130, and the first contact layer 120 and generally to the top surface of the first substrate layer 110. In some embodiments, the fourth scribe line P4 may extend into the first substrate layer 110. The fourth scribe lines P4 are separate from the third scribe lines P3 and are used to isolate the photovoltaic device array 1401 from the unusable edge portions of the photovoltaic assembly 1400 formed at the edge of the first substrate layer 110 of the photovoltaic assembly 1400. In some embodiments the fourth scribe lines P4 may be wide enough to extend to the edge of the photovoltaic assembly 1400. The fourth scribe lines P4 each include a surface that contains portions of the second contact layer 170, the second CTL 150, buffer layer 160, the absorber layer 140, the first CTL 130, the first contact layer 120, and the first substrate layer 110. The fourth scribe lines P4 may be formed by any suitable process, including, but not limited to, mechanical scribing systems, laser ablation, or combination thereof.

At operation 1550, as shown in FIG. 16J, one or more barrier layers 180 are formed over the previously formed device layer stack. The one or more barrier layers 180 are deposited over the second contact layer 170 and the exposed surfaces of the third scribe lines P3 and the fourth scribe lines P4, and partially fill the openings formed by the third scribe lines P3 and the fourth scribe lines P4. As previously discussed, the formed one or more barrier layers 180 are generally configured to encapsulate the device layer stack to prevent one or more layers within the device layer stack from being exposed to one or more environmental elements (e.g., water) that will cause damage to the one or more layers within the device layer stack and reduce the lifetime of the photovoltaic device.

The one or more barrier layers 180 include a barrier material. Each barrier layer of the one or more barrier layers 180 may include a different barrier material. The barrier materials of the one or more barrier layers 180 may include a metal oxide. In one example, the one or more barrier layers 180 include, but are not limited to, a material that comprises aluminum oxide, silicon oxide, tin oxide, titanium oxide, zirconium oxide, or combination thereof. The barrier materials of the one or more barrier layers 180 may include a styrenic polymer, a polysiloxane, an amine-containing polymer, a polyacrylate, an aryl ammonium halide, an alkyl ammonium halide, a fluorinated hydrocarbon polymer, or a combination thereof. In another example, the one or more barrier layers 180 include, but are not limited to, a styrenic polymer such as polystyrene (PS), acrylonitrile butadiene styrene (ABS), acrylonitrile-styrene-acrylate (ASA) or styrene-butadiene rubber (SBR). In another example, the one or more barrier layers 180 include, but are not limited to, a polysiloxane such as poly(dimethylsiloxane), poly(diethylsiloxane) or poly(methylphenylsiloxane). In another example, the one or more barrier layers 180 include, but are not limited to, a amine-containing polymer such as polyethylenimine (PEIE), poly(vinylamine) hydrochloride (PVH), or poly(ethylene glycol) bis(amine) (PEG-Amine). In another example, the one or more barrier layers 180 include, but are not limited to, a polyacrylate such as polymethylmethacrylate (PMMA) or polyethylacrylate. In another example, the one or more barrier layers 180 include, but are not limited to, an aryl ammonium halide such as phenethylammonium iodide (PEAI), 1-(ammonium acetyl)pyrene (PEY) or dodecyl ammonium-chloride (DACI). In another example, the one or more barrier layers 180 include, but are not limited to, an alkyl ammonium halide such as n-propylammonium iodide (PAI), ethane-1,2-diammonium (EDA), 2-chloro-ethylamine (CEA) or 2-bromo-ethylamine (BEA). In another example, the one or more barrier layers 180 include, but are not limited to, a fluorinated hydrocarbon polymer such as Nafion™, polytetrafluoroethylene, polyvinylidene-fluoride, or trifluoroethylene. The one or more barrier layers 180 have a barrier thickness between about 1 nm to about 5 μm, preferably between about 10 nm and 1500 nm, more preferably between about 20 nm and 1000 nm, more preferably yet between about 25 nm and 75 nm. For example, the thickness is greater than about 50 nm. For example, the thickness is about 1000 nm. The one or more barrier layers 180 may be conformally deposited by any suitable process, for example, a chemical vapor deposition (CVD) process, plasma enhanced chemical vapor deposition (PECVD) process, an atomic layer deposition (ALD) process, a plasma enhanced atomic layer deposition (PEALD) process, a physical vapor deposition (PVD) process (e.g., thermal evaporation), or solution processing methods such ink-jet printing, slot-die coating, spray-coating, gravure printing, blanket coating. In some embodiments, the solution processing methods include an annealing process. In some embodiments, the one or more barrier layers 180 are optically transparent to one or more wavelengths of light. In some embodiments, the formed one or more barrier layers 180 are at least semi-transparent to wavelengths of light greater than about 730 nm. In one example, the formed one or more barrier layers 180 have a transmittance of >80% at a wavelength of 700 nm. In some embodiments, the one or more barrier layers 180 comprise an aluminum oxide layer.

At operation 1555, as shown in FIG. 16K, an encapsulation layer 190 is disposed and/or formed over the device layer stack. As shown in FIG. 16K, the encapsulation layer 190 is disposed over the one or more barrier layers 180 and fills any remaining open area in the third scribe lines P3 and in fourth scribe lines P4. The encapsulation layer 190 includes an encapsulation material. The encapsulation material may include, but is not limited to, ethylene vinyl acetate (EVA), polyolefin, polyurethane, polyvinyl butyral, ionomers or combination thereof. The encapsulation layer 190 has an encapsulation thickness between about 0.1 mm to about 5 mm. The encapsulation layer 190 may be formed by any suitable process including, but not limited to, a lamination process, casting, an autoclave process, or other common deposition and/or attachment techniques.

At operation 1560, as shown in FIG. 16L, a second substrate layer 115 is disposed on and/or coupled to the encapsulation material. The second substrate layer 115 has a second substrate thickness between about 0.05 mm to about 5 mm. In some embodiments, as discussed above, second substrate layer 115 can include one or more materials selected from a group that includes a metal foil, silicon, glass, and/or a polymer substrate. In some embodiments, as discussed above, second substrate layer 115 is glass with a thickness between about 1 mm and 3 mm.

### Device Examples

Example 1. A photovoltaic device comprising: a first contact layer having a first thickness; a first charge transport layer (CTL) having a second thickness positioned over a surface of the first contact layer; an absorber layer having a third thickness positioned over a surface of the first CTL; a second CTL having a fourth thickness positioned over a surface of the absorber layer; a second contact layer having fifth thickness positioned over a surface of the second CTL, and a barrier layer, wherein: the barrier layer is positioned adjacent to and in contact with at least a portion of at least one of the surfaces of the first contact layer, the first CTL, the absorber layer, the second CTL, or the second contact layer, and the barrier layer comprises a material that is insoluble in water. As referenced herein, a material that is considered to be insoluble in water will generally include a material that has a water vapor transmission rate (WVTR) that is less than about 6 g/(m² day) for materials such as PEIE/CYTOP, or less than about 4×10⁻² g/(m² day) for materials such as alumina, as measured using a standard WVTR test (e.g., ASTM WVTR standard tests).

Example 2. The photovoltaic device of Example 1, further comprising: a first scribe line defined by at least one surface, wherein the at least one surface of the first scribe line comprises at least a portion of at least one of the first thickness, the second thickness, the third thickness, the fourth thickness, or the fifth thickness, and the material of the barrier layer is disposed over at least a portion of the at least one surface of the first scribe line.

Example 3. The photovoltaic device of either Example 1 or Example 2, wherein the at least one surface formed by the first scribe line is positioned substantially perpendicular to at least one of the surfaces of the first contact layer, the first CTL, the absorber layer, the second CTL, or the second contact layer.

Example 4. The photovoltaic device of any one of Examples 1-3, wherein the first scribe line has a width between 5 μm and 200 μm.

Example 5. The photovoltaic device of any one of Examples 1-4, further comprising: a second scribe line defined by at least one surface, wherein the at least one surface of the second scribe line comprises at least a portion of at least one of the first thickness, the second thickness, the third thickness, the fourth thickness, or the fifth thickness, and the material of the barrier layer is disposed over at least a portion of the at least one surface of the second scribe line.

Example 6. The photovoltaic device of any one of Examples 1-5, wherein the at least one surface formed by the second scribe line is positioned substantially perpendicular to at least one of the surfaces of the first contact layer, the first CTL, the absorber layer, the second CTL, or the second contact layer.

Example 7. The photovoltaic device of any one of Examples 1-6, wherein the second scribe line has a width between 5 μm and 200 μm.

Example 8. The photovoltaic device of any one of Examples 1-7, wherein the material of the barrier layer comprises at least one of a metal oxide, a polymer, a resin, an aryl ammonium halide, an alkyl ammonium halide, or lead sulphate.

Example 9. The photovoltaic device of any one of Examples 1-8, wherein the metal oxide comprises at least one of aluminum oxide, silicon oxide, tin oxide, zirconium oxide, or titanium oxide.

Example 10. The photovoltaic device of any one of Examples 1-9, wherein the aryl ammonium halide comprises at least one of phenethylammonium iodide (PEAI), 1-(ammonium acetyl)pyrene (PEY), or dodecyl ammonium-chloride (DACI).

Example 11. The photovoltaic device of any one of Examples 1-10, wherein the alkyl ammonium halide comprises ate least one of n-propylammonium iodide (PAI), ethane-1,2-diammonium (EDA), 2-choloro-ethylamine (CEA), or 2-bromo-ethylamine (BEA).

Example 12. The photovoltaic device of any one of Examples 1-11, wherein the polymer comprises at least one of a styrenic polymer, a polysiloxane, an amine-containing polymer, a polyacrylate, or a fluorinated hydrocarbon polymer.

Example 13. The photovoltaic device of any one of Examples 1-12, wherein the amine-containing polymer comprises at least one of polyethylenimine (PEIE), poly(vinylamine) hydrochloride (PVH), or poly(ethylene glycol) bis(amine) (PEG-Amine).

Example 14. The photovoltaic device of any one of Examples 1-13, wherein the polysiloxane comprises at least one of poly(dimethylsiloxane), poly(diethylsiloxane), or poly(methylphenylsiloxane).

Example 15. The photovoltaic device of any one of Examples 1-14, wherein the polyacrylate comprises at least one of polymethylmethacrylate (PMMA), polymethylacrylate (PMA), or polyethylacrylate.

Example 16. The photovoltaic device of any one of Examples 1-15, wherein the styrenic polymer comprises at least one of polystyrene (PS), acrylonitrile butadiene styrene (ABS), acrylonitrile-styrene-acrylate (ASA), or styrene-butadiene rubber (SBR).

Example 17. The photovoltaic device of any one of Examples 1-16, wherein the fluorinated hydrocarbon polymer comprises at least one of Nafion™, polytetrafluoroethylene, polyvinylidene-fluoride, or trifluoroethylene.

Example 18. The photovoltaic device of any one of Examples 1-17, wherein the fluorinated hydrocarbon polymer has a structure as defined by (I),

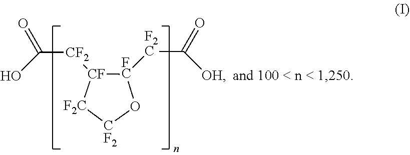

Example 19. The photovoltaic device of any one of Examples 1-18, wherein the material of the barrier layer at least partially fills at least one of the first scribe line or the second scribe line.

Example 20. The photovoltaic device of any one of Examples 1-19, wherein the barrier layer has a thickness between 20 nm and 1500 nm.

Example 21. The photovoltaic device of any one of Examples 1-20, wherein the material of the barrier layer has a transmittance of greater than 80% at wavelengths greater than 700 nm as measured through the thickness of the barrier layer.

Example 22. The photovoltaic device of any one of Examples 1-21, wherein the thickness of the barrier layer is between 1 nm and 2 μm.

Example 23. The photovoltaic device of any one of Examples 1-22, wherein the thickness of the barrier layer is between 1 nm and 2 μm.

Example 24. The photovoltaic device of any one of Examples 1-23, wherein the thickness of the barrier layer is between 50 nm and 100 nm.

Example 25. The photovoltaic device of any one of Examples 1-24, wherein: the barrier layer comprises at least a first layer and a second layer, the first layer comprises a first material, and the second layer comprises a second material that is different from the first material.

Example 26. The photovoltaic device of any one of Examples 1-25, wherein the first material comprises a first metal oxide and the second material comprises a second metal oxide.

Example 27. The photovoltaic device of any one of Examples 1-26, wherein the first metal oxide comprises silicon oxide and the second metal oxide comprises aluminum oxide.

Example 28. The photovoltaic device of any one of Examples 1-27, wherein the first material comprises a first polymer and the second material comprises a second polymer.

Example 29. The photovoltaic device of any one of Examples 1-28, wherein the first polymer comprises at least one of PMMA, PS, PEIE, or a fluorinated hydrocarbon polymer.

Example 30. The photovoltaic device of any one of Examples 1-29, wherein the second polymer comprises at least one of PMMA, PS, PEI, or a fluorinated hydrocarbon polymer.

Example 31. The photovoltaic device of any one of Examples 1-30, wherein the first polymer comprises PEIE and the second polymer comprises a fluorinated hydrocarbon polymer.

Example 32. The photovoltaic device of any one of Examples 1-31, wherein the first contact layer comprises at least one of aluminum, copper, silver, gold, indium tin oxide (ITO), fluorine doped tin oxide (FTO), or indium zinc oxide (IZO).

Example 33. The photovoltaic device of any one of Examples 1-32, wherein the second contact layer comprises at least one of aluminum, copper, silver, gold, indium tin oxide (ITO), fluorine doped tin oxide (FTO), or indium zinc oxide (IZO).

Example 34. The photovoltaic device of any one of Examples 1-33, further comprising a buffer layer positioned between the absorber layer and the second contact layer.

Example 35. The photovoltaic device of any one of Examples 1-34, the buffer layer comprises an oxysalt. The term “oxysalt” will generally refer to a chemical compound or specie having at least one cation and at least one anion associated with each other via ionic bonding, wherein at least one anion includes an oxygen atom (O) in its chemical formula. In an embodiment, an oxysalt may be characterized as an oxyacid. An oxysalt may comprise an organic cation and/or a cation that is H+.

Example 36. The photovoltaic device of any one of Examples 1-35, wherein the second charge transport layer comprises fullerenes.

Example 37. The photovoltaic device of any one of Examples 1-36, wherein the absorber layer comprises at least one of a perovskite, silicon, a III-V alloy, an organic photovoltaic material, a dye-sensitized material, a copper indium gallium selenide alloy, or a cadmium telluride alloy.

Example 38. The photovoltaic device of any one of Examples 1-37, wherein the absorber layer comprises a perovskite which comprises at least one three-dimensional (3D) structure, a two-dimensional (2D) structure, a one-dimensional (1D) structure, or a zero-dimensional (0D) structure.

Example 39. The photovoltaic device of any one of Examples 1-38, wherein: the 3D structure comprises ABX₃, A comprises a first cation, B comprises a second cation, and X comprises an anion.

Example 40. The photovoltaic device of any one of Examples 1-39, wherein the first cation comprises at least one of formamidinium (FA), methylammonium (MA), or cesium.

Example 41. The photovoltaic device of any one of Examples 1-40, wherein the second cation comprises at least one of tin or lead.

Example 42. The photovoltaic device of any one of Examples 1-41, wherein the anion comprises a halide.

Example 43. The photovoltaic device of any one of Examples 1-42, wherein the first scribe line passes through the third thickness and at least a portion of the second thickness.

Example 44. The photovoltaic device of any one of Examples 1-43, wherein the third thickness is between 200 nm and 1500 nm.

Example 45. The photovoltaic device of any one of Examples 1-44, wherein the second thickness is between 1 nm and 1000 nm.

Example 46. The photovoltaic device of any one of Examples 1-45, wherein the first scribe line passes through the fourth thickness and the fifth thickness.

Example 47. The photovoltaic device of any one of Examples 1-46, wherein the fourth thickness is between 1 nm and 1000 nm.

Example 48. The photovoltaic device of any one of Examples 1-47, wherein the fifth thickness is between 1 nm and 1000 nm.

Example 49. The photovoltaic device of any one of Examples 1-48, further comprising an encapsulation layer, wherein the barrier layer is positioned between the encapsulation layer and the second contact layer.

Example 50. The photovoltaic device of any one of Examples 1-49, wherein the encapsulation layer comprises at least one of aluminum oxide, silicon oxide, PMMA, PS, a fluorinated hydrocarbon polymer, or PEIE.

Example 51. The photovoltaic device of any one of Examples 1-50, wherein the barrier layer has a thickness that is sufficiently thin to allow charge tunnelling to occur when the barrier layer is positioned between the absorber layer and the second contact layer.

Example 52. The photovoltaic device of any one of Examples 1-51, wherein the barrier layer is positioned between the absorber layer and the second contact layer.

Example 53. The photovoltaic device of any one of Examples 1-52, wherein the barrier layer is positioned between the absorber layer and the second CTL.

Example 54. The photovoltaic device of any one of Examples 1-53, wherein the second contact layer is positioned between the barrier layer and the absorber layer.

Example 55. The photovoltaic device of any one of Examples 1-54, wherein the second CTL is positioned between the barrier layer and the absorber layer.

Example 56. A photovoltaic device comprising: a first contact layer having a first thickness; a first charge transport layer (CTL) having a second thickness positioned over a surface of the first contact layer; an absorber layer having a third thickness positioned over a surface of the first CTL; a second CTL having a fourth thickness positioned over a surface of the absorber layer; a second contact layer having fifth thickness positioned over a surface of the second CTL; a barrier layer comprising a metal oxide; an encapsulation layer; and a first scribe line defined by at least one surface, wherein: the absorber layer comprises ABX3, where A is a first cation, B is a second cation, and X comprises at least one halide, at least a portion of the barrier layer is positioned between the encapsulation layer and the second CTL, the scribe line passes through the third thickness, fourth thickness, fifth thickness, and at least a portion of the second thickness, and the metal oxide is disposed over at least a portion of the at least one surface formed by the first scribe line.

### Method Examples

Example 57. A method of fabricating a photovoltaic device stack, comprising: forming a barrier layer on a photovoltaic device layer stack, wherein the device layer stack comprises: a first contact layer having a first thickness; a first charge transport layer (CTL) having a second thickness positioned over a surface of the first contact layer; an absorber layer having a third thickness positioned over a surface of the first CTL; a second CTL having a fourth thickness positioned over a surface of the absorber layer; a second contact layer having fifth thickness positioned over a surface of the second CTL; and a scribe line defined by at least one surface, wherein: the at least one surface of the scribe line comprises at least a portion of the third thickness, fourth thickness, fifth thickness, and at least a portion of the second thickness, the barrier layer comprises at least one of a metal oxide, a polymer, a resin, an aryl ammonium halide, an alkyl ammonium halide, or lead sulphate, and the barrier layer is formed over at least a portion of the at least one surface of the first scribe line.

Example 58. The method of Example 57, wherein: the device stack further comprises a second scribe line, the second scribe line is defined by at least one surface, the at least one surface of the second scribe line comprises at least a portion of the first thickness, the second thickness, the third thickness, the fourth thickness, or the fifth thickness, and the barrier layer is disposed over at least a portion of the at least one surface of the second scribe line.

Example 59. The method of either Example 57 or Example 58, further comprising forming an encapsulation layer over the second contact layer, wherein at least a portion of the barrier layer is positioned between the encapsulation layer and the second contact layer.

Example 60. The method of any one of Examples 57-59, wherein the barrier layer comprises the metal oxide, and the metal oxide comprises aluminum oxide, silicon oxide, tin oxide, zirconium oxide, titanium oxide, or a combination thereof.

Example 61. The method of any one of Examples 57-60, wherein the barrier layer has a thickness between 20 nm and 1500 nm.

Example 62. The method of any one of Examples 57-61, wherein the barrier layer has a transmittance of greater than 80% at wavelengths greater than 700 nm as measured through the thickness of the barrier layer.

Example 63. The method of any one of Examples 57-62, wherein: the forming comprises at least one of a solution processing step or a vapor phase processing step, and the processing step deposits at least one of the barrier layer material or a barrier layer material precursor onto the photovoltaic device stack.

Example 64. The method of any one of Examples 57-63, wherein the vapor phase processing step comprises at least one of atomic layer deposition (ALD) or thermal evaporation.

Example 65. The method of any one of Examples 57-63, wherein the metal oxide comprises Al₂O₃ deposited by ALD.

Example 66. The method of any one of Examples 57-65, wherein the metal oxide comprises silicon oxide deposited by thermal evaporation.

Example 67. The method of any one of Examples 57-66, wherein: the solution processing step comprises applying an ink comprising a polymer and a liquid, and the liquid at least one of suspends the barrier layer material or dissolves the barrier layer material.

Example 68. The method of any one of Examples 57-67, wherein the barrier layer material comprising at least one of polystyrene, polydimethylsiloxane (PDMS), polyethylenimine (PEI); polymethylmethacrylate (PMMA), lead sulphate, phenethylammonium iodide (PEAI), or a fluorinated hydrocarbon polymer.

Example 69. The ink of any one of Examples 57-68, wherein the liquid comprises an acetate.

Example 70. The ink of any one of Examples 57-69, wherein the acetate comprises at least one of ethyl acetate or methyl acetate.

The foregoing discussion and examples have been presented for purposes of illustration and description. The foregoing is not intended to limit the aspects, embodiments, or configurations to the form or forms disclosed herein. In the foregoing Detailed Description, various features of the aspects, embodiments, or configurations are grouped together in one or more embodiments, configurations, or aspects for the purpose of streamlining the disclosure. The features of the aspects, embodiments, or configurations may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

What is claimed is:

1. A photovoltaic device comprising:
a first contact layer having a first thickness;
a first charge transport layer (CTL) having a second thickness positioned over a surface of the first contact layer;
an absorber layer having a third thickness positioned over a surface of the first CTL;
a second CTL having a fourth thickness positioned over a surface of the absorber layer;
a second contact layer having fifth thickness positioned over a surface of the second CTL;
a barrier layer having a sixth thickness;
an encapsulation layer; and
a first scribe line defined by at least one surface, wherein:
at least a portion of the barrier layer is positioned between the encapsulation layer and the second CTL,
the at least one surface of the scribe line comprises at least a portion of the third thickness, fourth thickness, fifth thickness, and at least a portion of the second thickness, and
the barrier layer is disposed over at least a portion of the at least one surface formed by the first scribe line.

2. The photovoltaic device of claim 1, further comprising:
a second scribe line defined by at least one surface, wherein:
the at least one surface of the second scribe line comprises at least a portion of the second thickness, third thickness, fourth thickness, and fifth thickness, and
the barrier layer is disposed over at least a portion of the at least one surface of the second scribe line.

3. The photovoltaic device of claim 2, wherein the at least one surface of the first scribe line comprises a portion of the first contact layer, first CTL layer, the absorber layer, second CTL layer, and second contact layer.

4. The photovoltaic device of claim 1, wherein the absorber layer comprises ABX3, where A is a first cation, B is a second cation, and X comprises at least one halide.

5. The photovoltaic device of claim 4, wherein the second cation comprises at least one of tin or lead.

6. The photovoltaic device of claim 5, wherein the first cation comprises at least one of formamidinium (FA), methylammonium (MA), or cesium.

7. The photovoltaic device of claim 1, wherein the barrier layer comprises at least one of a metal oxide, a polymer, a resin, an aryl ammonium halide, an alkyl ammonium halide, or lead sulphate.

8. The photovoltaic device of claim 7, wherein the metal oxide comprises at least one of aluminum oxide, silicon oxide, tin oxide, zirconium oxide, or titanium oxide.

9. The photovoltaic device of claim 7, wherein the aryl ammonium halide comprises at least one of phenethylammonium iodide (PEAI), 1-(ammonium acetyl)pyrene (PEY), or dodecyl ammonium-chloride (DACI).

10. The photovoltaic device of claim 1, wherein the barrier layer has a thickness between 20 nm and 1500 nm.

11. The photovoltaic device of claim 10, wherein the barrier layer has a transmittance of greater than 80% at wavelengths greater than 700 nm as measured through the thickness of the barrier layer.

12. The photovoltaic device of claim 1, further comprising a buffer layer positioned between the absorber layer and the second contact layer, and the buffer layer comprises an oxysalt.

13. The photovoltaic device of claim 1, wherein the second charge transport layer comprises fullerenes.

14. The photovoltaic device of claim 1, wherein the absorber layer comprises at least one of a perovskite, silicon, a III-V alloy, an organic photovoltaic material, a dye-sensitized material, a copper indium gallium selenide alloy, or a cadmium telluride alloy.

15. The photovoltaic device of claim 1, wherein the barrier layer comprises a material that is insoluble in water.

16. A method of fabricating a photovoltaic device stack, the method comprising:
forming a barrier layer on a photovoltaic device layer stack, wherein the device layer stack comprises:
a first contact layer having a first thickness;
a first charge transport layer (CTL) having a second thickness positioned over a surface of the first contact layer;
an absorber layer having a third thickness positioned over a surface of the first CTL;
a second CTL having a fourth thickness positioned over a surface of the absorber layer;
a second contact layer having fifth thickness positioned over a surface of the second CTL; and
a first scribe line defined by at least one surface,
wherein:
the at least one surface of the first scribe line comprises at least a portion of the third thickness, fourth thickness, fifth thickness, and at least a portion of the second thickness,
the barrier layer comprises at least one of a metal oxide, a polymer, a resin, an aryl ammonium halide, an alkyl ammonium halide, or lead sulphate, and
the barrier layer is formed over at least a portion of the at least one surface of the first scribe line.

17. The method of claim 16, wherein:
the device stack further comprises a second scribe line,
the second scribe line is defined by at least one surface,
the at least one surface of the second scribe line comprises at least a portion of the first thickness, the second thickness, the third thickness, the fourth thickness, or the fifth thickness, and
the barrier layer is disposed over at least a portion of the at least one surface of the second scribe line.

18. The method of claim 16, wherein the barrier layer comprises the metal oxide, and the metal oxide comprises aluminum oxide, silicon oxide, tin oxide, zirconium oxide, titanium oxide, or a combination thereof.

19. The method of claim 16, wherein the barrier layer has a thickness between 20 nm and 1500 nm, and the barrier layer has a transmittance of greater than 80% at wavelengths greater than 700 nm as measured through the thickness of the barrier layer.

20. The method of claim 16, wherein the barrier layer comprises a material that is insoluble in water.
